(19) United States
(12) Patent Application Publication
(10) Pub. No.: US 2014/0159489 A1
(43) Pub. Date: Jun. 12, 2014

(54) WHEELCHAIR SOLAR CANOPY

(71) Applicant: ALTORR, INC., Largo, FL (US)

(72) Inventor: Bradford A. Clough, Largo, FL (US)

(73) Assignee: ALTORR, INC., Largo, FL (US)

(21) Appl. No.: 13/710,455

(22) Filed: Dec. 10, 2012

(51) Int. Cl. H01L 31/048; H02J 1/00

(52) U.S. Cl. CPC H01L 31/048; H02J 1/00
USPC 307/43; 136/251

(57) ABSTRACT

Systems, methods and apparatus are provided through which in some implementations a solar canopy for a motorized wheelchair includes a solar panel fitted into a recess in the solar canopy and a top cover in another recess at the top of the solar canopy and over the solar panel.

### RELATED APPLICATIONS

This application claims priority of provision patent application 61/568,697 filed on 9 Dec. 2011.

### FIELD

This disclosure relates generally to vehicle solar canopies, and more particularly to wheelchair solar canopies.

### BACKGROUND

Conventional solar canopies have a complex structure, such as patent Ser. No. 12/417,159 by inventor David Kurt Schneider.

### BRIEF DESCRIPTION

The above-mentioned shortcomings, disadvantages and problems are addressed herein, which will be understood by reading and studying the following specification.

This disclosure relates generally to solar canopies, and more particularly to the power systems of wheelchair solar canopies.

Apparatus, systems, and methods of varying scope are described herein. In addition to the aspects and advantages described in this summary, further aspects and advantages will become apparent by reference to the drawings and by reading the detailed description that follows.

### BRIEF DESCRIPTION OF THE DRAWINGS

FIG. 1 is an isometric diagram of a top/side view of a solar canopy with a solar panel without a top cover and having a main body, according to an implementation;

FIG. 2 is an isometric diagram of a bottom/side view of a solar canopy with a bottom cover and frame attachment plates, according to an implementation;

FIG. 3 is an isometric cross-section diagram of a bottom/side view of a solar canopy without a top cover, with a bottom cover, with a solar panel and having an frame attachment plate, according to an implementation;

FIG. 4 is an isometric cross-section diagram of a top/side view of a solar canopy without a top cover, with a bottom cover, having a solar panel and having bottom cover attachment plates, according to an implementation;

FIG. 5 is an isometric cross-section diagram of a top/side view of a solar canopy without a top cover, with a bottom cover and having a solar panel, according to an implementation;

FIG. 6 is an isometric diagram of a top/front/side view of a solar canopy without a solar panel, without a top cover and having a corrugated main body, according to an implementation;

FIG. 7 is a diagram of a bottom view of a solar canopy without a bottom cover and having a corrugated main body with bottom cover attachment plates and frame attachment plates, according to an implementation;

FIG. 8 is an isometric cross-section diagram of a bottom/side view of a solar canopy without a top cover, without a bottom cover, without a solar panel and having a corrugated main body with bottom cover attachment plates and frame attachment plate, according to an implementation;

FIG. 9 is an isometric cross-section diagram of a side view of a solar canopy without a top cover, with a bottom cover, having a solar panel and having a corrugated main body, according to an implementation;

FIG. 10 is an isometric cross-section diagram of a bottom/side view of a solar canopy without a top cover, with a bottom cover, having a solar panel, having a corrugated main body and frame attachment plates, according to an implementation;

FIG. 11 is an isometric diagram of a bottom/side view of a solar canopy without a bottom cover, having a corrugated main body with bottom cover attachment plates and frame attachment plates, according to an implementation;

FIG. 12 is an isometric diagram of a bottom/side view of a solar canopy without a bottom cover, having a corrugated main body with bottom cover attachment plates and frame attachment plates, according to an implementation; and

FIG. 13 is an isometric diagram of a bottom/side view of a solar canopy system without a bottom cover, and having a folding frame in fully extended position, according to an implementation;

FIG. 14 is an isometric cross-section diagram of a top/side view of a solar canopy system without a top cover, without a solar panel and having a folding frame in fully extended position, according to an implementation;

FIG. 15 is an isometric diagram of a bottom/front view of a solar canopy system without a bottom cover, and having a folding frame in fully extended position, according to an implementation;

FIG. 16 is an isometric diagram of a bottom/side view of a solar canopy system without a bottom cover, and having a folding frame in fully extended position, according to an implementation;

FIG. 17 is an isometric diagram of a bottom/side view of a solar canopy system without a bottom cover, and having a folding frame in first folded position, according to an implementation;

FIG. 18 is an isometric diagram of a bottom/side view of a solar canopy system without a bottom cover, and having a folding frame in second folded position, according to an implementation;

FIG. 19 is an isometric diagram of a bottom/side view of a solar canopy system without a bottom cover, and having a folding frame in third folded position, according to an implementation;

FIG. 20 is an isometric diagram of a bottom/side view of a solar canopy system without a bottom cover, and having a folding frame in fourth folded position, according to an implementation;

FIG. 21 is an isometric diagram of a bottom/side view of a solar canopy system without a bottom cover, and having a folding frame in fifth folded position, according to an implementation; and

FIG. 22 is an isometric diagram of a bottom/side view of a solar canopy system without a bottom cover, and having a folding frame in completely folded position, according to an implementation.

### DETAILED DESCRIPTION

In the following detailed description, reference is made to the accompanying drawings that form a part hereof, and in which is shown by way of illustration specific implementations which may be practiced. These implementations are described in sufficient detail to enable those skilled in the art to practice the implementations, and it is to be understood that other implementations may be utilized and that logical, mechanical, electrical and other changes may be made without departing from the scope of the implementations. The following detailed description is, therefore, not to be taken in a limiting sense.

The detailed description is divided into five sections. In the first section, a system level overview is described. In the second section, apparatus of implementations are described. In the third section, implementations of methods are described. In the fourth section, a hardware and the operating environment in conjunction with which implementations may be practiced are described. Finally, in the fifth section, a conclusion of the detailed description is provided.

Apparatus Implementations

In this section, the particular apparatus of implementations are described by reference to a series of diagrams.

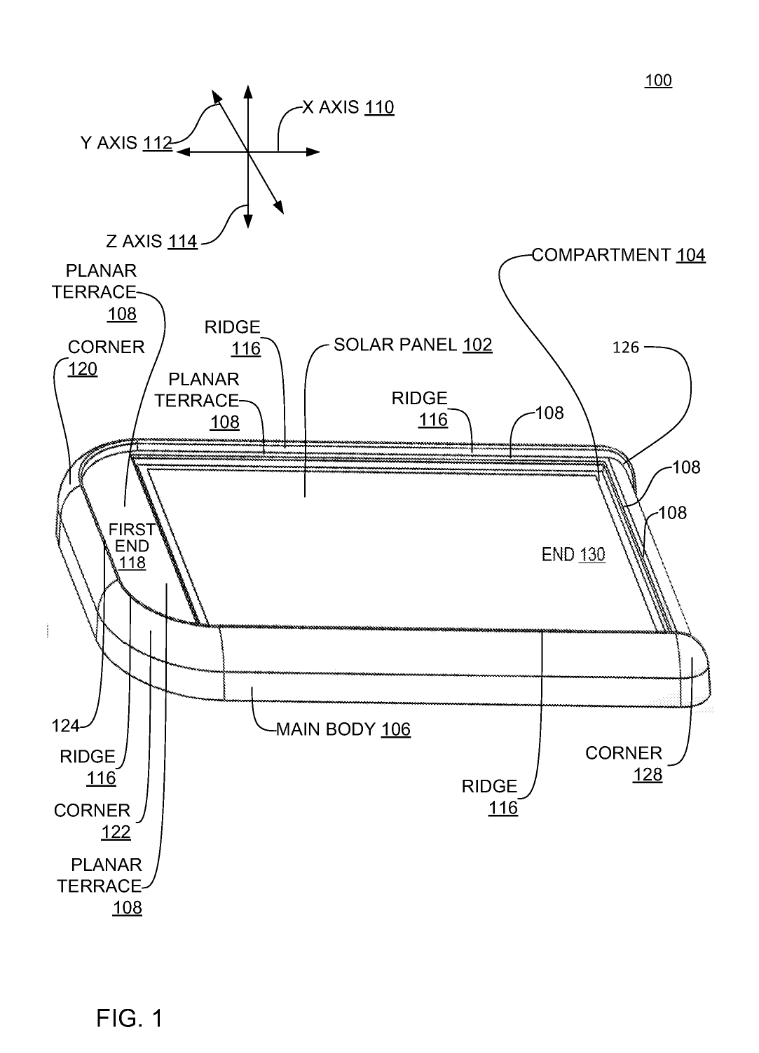

FIG. 1 is an isometric diagram of a top/side view of a solar canopy 100 with a solar panel, without a top cover and having a main body to collect solar energy, according to an implementation.

Solar canopy 100 includes a solar panel 102. The solar panel 102 is positioned in a compartment 104 of a main body 106 of the solar canopy 100. In some implementations, the solar panel 102 is removeably attached to one or more interior surfaces of the compartment 104 using an apparatus such as screws, a hook-and-loop apparatus such as Velcro®, or nuts and bolts. In other implementations, the solar panel 102 is not attached to any of the interior surfaces of the compartment 104 in which the solar panel 102 is held in place by the operation of gravity upon the solar panel 102 when the solar canopy 100 is positioned in an up/down orientation such as shown in FIG. 1. The compartment 104 is a recessed area within the main body that in some implementations is enclosed on five sides of the compartment 104 and in which one side is open that allows the solar panel 102 to be placed within the compartment 104 and when the solar panel 102 is not attached or removeably attached w/in the compartment 104 the solar panel 102 can be removed from the compartment 104 through the open side of the compartment 104.

The main body 106 of the solar canopy 100 also includes a planar terrace 108. The function of the planar terrace 108 is to receive a planar cover (not shown) that contacts the planar terrace 108 along all or substantially all of the planar terrace 108 and that provides support and stability to the planar cover along an X axis 110 and an Y axis 112 that inhibits movement of the solar canopy along a Z axis 114.

The solar panel 102 is positioned within the compartment 104 parallel to the planar terrace 108 along the Z axis 114 and the solar panel 102 is positioned at a different position to the compartment 104 along the Z axis 114. The compartment 104 is a recess to the planar terrace 108.

In some implementations, the main body 106 of the solar panel 102 also includes a lip or a ridge 116 at the outer perimeter of the planar terrace 108. The ridge inhibits movement of a cover along the X axis 110 and the Y axis 112. The ridge is open on one side (the top side) that allows the solar panel 102 to be placed in and removed from the main body 106 of the solar canopy 100.

Along a first end 118 of the main body 106 of the solar canopy 100, the corners 120 and 122 of the main body 106 are rounded. In some implementations, the corners 120 and 122 are rounded with a greater radius than shown in FIG. 1 to the extent that there is no straight line surface 124 between the rounded corners 120 and 122 in which the two rounded corners 120 and 122 merge into one continuously rounded hemispheric half-circular corner. Some implementations of the main body 106 the solar canopy 100 also includes rounded corners 126 and 128 on the opposite end 130 from end 118. While the solar canopy 100 is not limited to any particular solar panel 102, a compartment 104, a main body 106, a planar terrace 108, an X axis 110, an Y axis 112, a Z axis 114, a lip or a ridge 116, a first end 118 of the main body 106, corners 120 and 122 of the main body 106, a straight line surface 124, rounded corners 126 and 128 on the opposite end 130, for sake of clarity a simplified solar panel and a solar panel 102, a compartment 104, a main body 106, a planar terrace 108, an X axis 110, an Y axis 112, a Z axis 114, a lip or a ridge 116, a first end 118 of the main body 106, corners 120 and 122 of the main body 106, a straight line surface 124, rounded corners 126 and 128 on the opposite end 130 are described.

The solar panel 102 (also known as solar module, photovoltaic module or photovoltaic panel) is a packaged, connected assembly of photovoltaic cells. The solar panel 102 can be used as a component of a larger photovoltaic system to generate and supply electricity in commercial and residential applications. Each panel is rated by its DC output power under standard test conditions, and typically ranges from 100 to 320 watts. The efficiency of a panel determines the area of a panel given the same rated output—an 8% efficient 230 watt panel will have twice the area of a 16% efficient 230 watt panel. Because a single solar panel can produce only a limited amount of power, most installations contain multiple panels. A photovoltaic system typically includes an array of solar panels, an inverter, and sometimes a battery and or solar tracker and interconnection wiring. Solar panels use light energy (photons) from the sun to generate electricity through the photovoltaic effect. The majority of modules use wafer-based crystalline silicon cells or thin-film cells based on cadmium telluride or silicon. The structural (load carrying) member of a module can either be the top layer or the back layer. Cells must also be protected from mechanical damage and moisture. Most solar panels are rigid, but semi-flexible ones are available, based on thin-film cells. Electrical connections are made in series to achieve a desired output voltage and/or in parallel to provide a desired current capability. The conducting wires that take the current off the panels may contain silver, copper or other non-magnetic conductive transition metals. The cells must be connected electrically to one another and to the rest of the system. Externally, popular terrestrial usage photovoltaic panels use MC3 (older) or MC4 connectors to facilitate easy weatherproof connections to the rest of the system. Bypass diodes may be incorporated or used externally, in case of partial panel shading, to maximize the output of panel sections still illuminated. The p-n junctions of mono-crystalline silicon cells may have adequate reverse voltage characteristics to prevent damaging panel section reverse current. Reverse currents could lead to overheating of shaded cells. Solar cells become less efficient at higher temperatures and installers try to provide good ventilation behind solar panels. Some recent solar panel designs include concentrators in which light is focused by lenses or mirrors onto an array of smaller cells. This enables the use of cells with a high cost per unit area (such as gallium arsenide) in a cost-effective way.

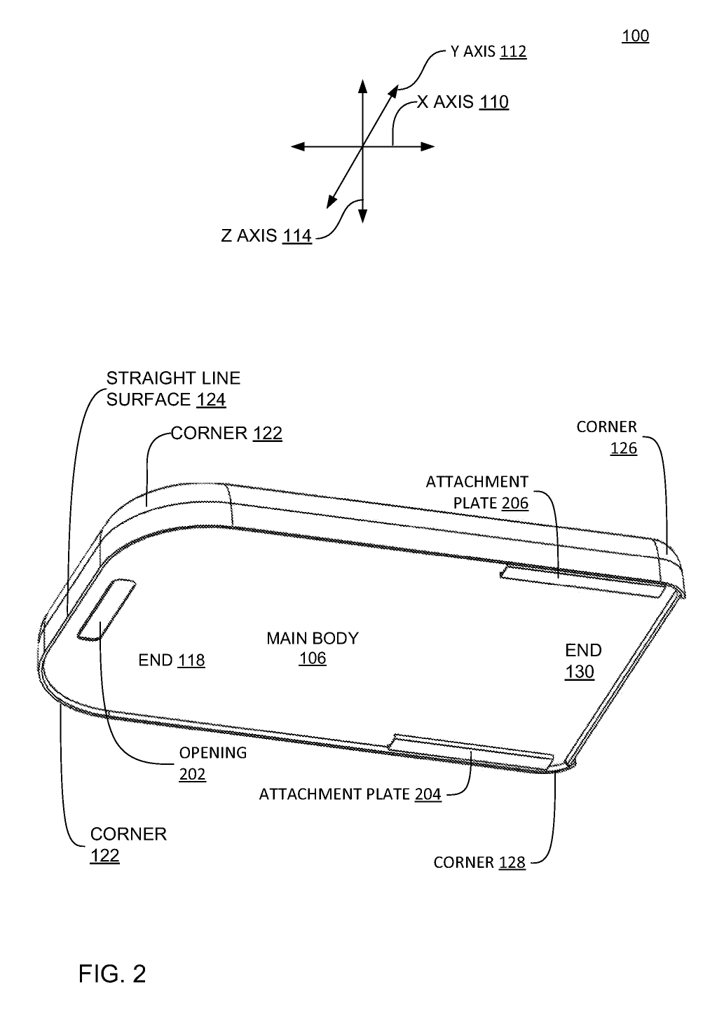

FIG. 2 is an isometric diagram of a bottom/side view of a solar canopy with a bottom cover and frame attachment plates, according to an implementation. Solar canopy 100 includes a main body 106. Along a first end 118 of the main body 106 of the solar canopy 100, the corners 120 and 122 of the main body 106 are rounded. In some implementations, the corners 120 and 122 are rounded with a greater radius than shown in FIG. 2 to the extent that there is no straight line surface 124 between the rounded corners 120 and 122 in which the two rounded corners 120 and 122 merge into one continuously rounded hemispheric half-circular corner. Some implementations of the main body 106 the solar canopy 100 also includes rounded corners 126 and 128 on the opposite end 130 from end 118. Solar canopy 100 also includes an opening 202. Frame attachment plates 204 and 206 operably couple a folding frame (shown in FIG. 13-22) to the main body 106.

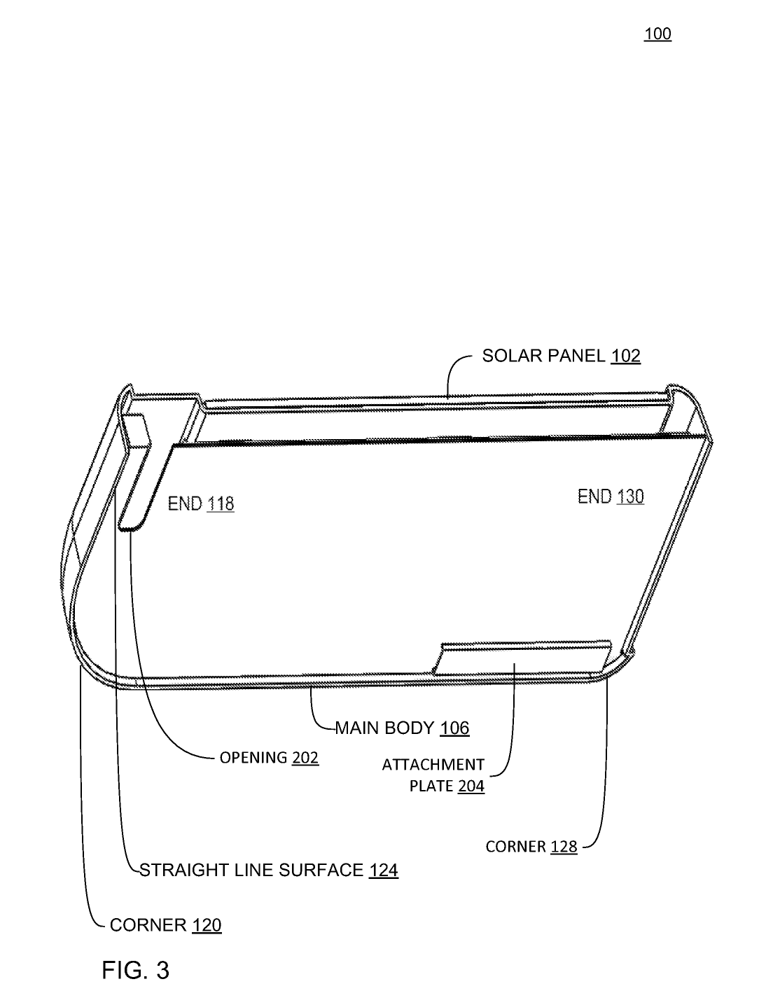

FIG. 3 is an isometric cross-section diagram of a bottom/side view of a solar canopy without a top cover, with a bottom cover, without a solar panel and having an frame attachment plate flat compartment for the solar panel, according to an implementation. Solar canopy 100 includes a main body 106. Along a first end 118 of the main body 106 of the solar canopy 100, the corner 120 of the main body 106 is rounded. In some implementations, the corner 120 is rounded with a greater radius than shown in FIG. 3 to the extent that there is no straight line surface 124 between the rounded corners 122 (shown in FIGS. 2) and 120 in which the rounded corner 122 (shown in FIGS. 2) and 120 merge into one continuously rounded hemispheric half-circular corner. Some implementations of the main body 106 the solar canopy 100 also includes rounded corner 128 on the opposite end 130 from end 118. Solar canopy 100 also includes an opening 202. Frame attachment plate 204 operably couples a folding frame (shown in FIG. 13-22) to the main body 106.

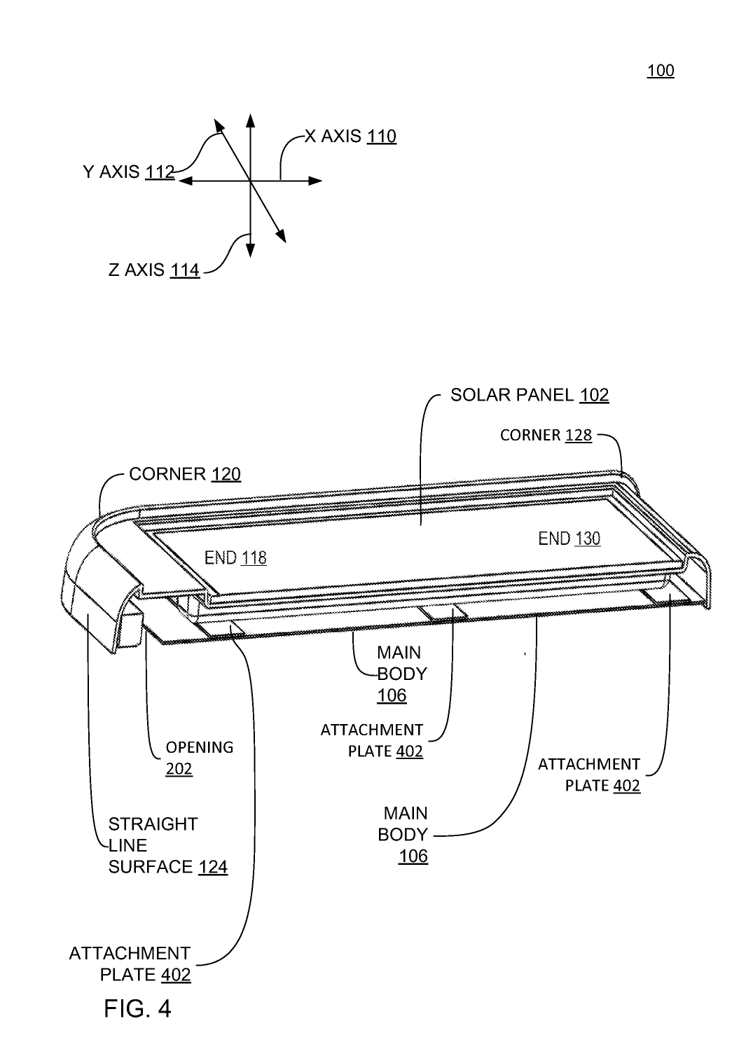

FIG. 4 is an isometric cross-section diagram of a top/side view of a solar canopy without a top cover, with a bottom cover, having a solar panel and having bottom cover attachment plates, according to an implementation. Solar canopy 100 includes a main body 106. Along a first end 118 of the main body 106 of the solar canopy 100, the corner 120 of the main body 106 is rounded. In some implementations, the corner 120 is rounded with a greater radius than shown in FIG. 4 to the extent that there is no straight line surface 124 between the rounded corners 122 (shown in FIGS. 2) and 120 in which the rounded corner 122 (shown in FIGS. 2) and 120 merge into one continuously rounded hemispheric half-circular corner. Some implementations of the main body 106 the solar canopy 100 also includes rounded corner 128 on the opposite end 130 from end 118. Solar canopy 100 also includes an opening 202. Bottom cover attachment plates 402 are operable to fixedly attach the bottom of the main body 106 to a bottom cover (not shown).

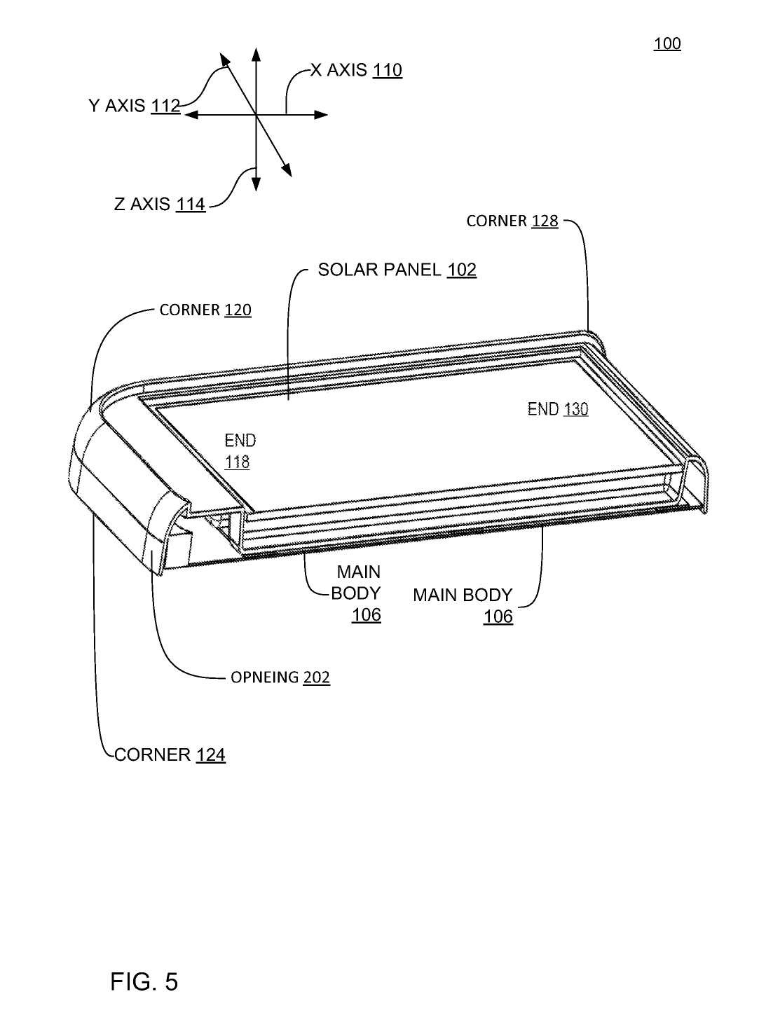

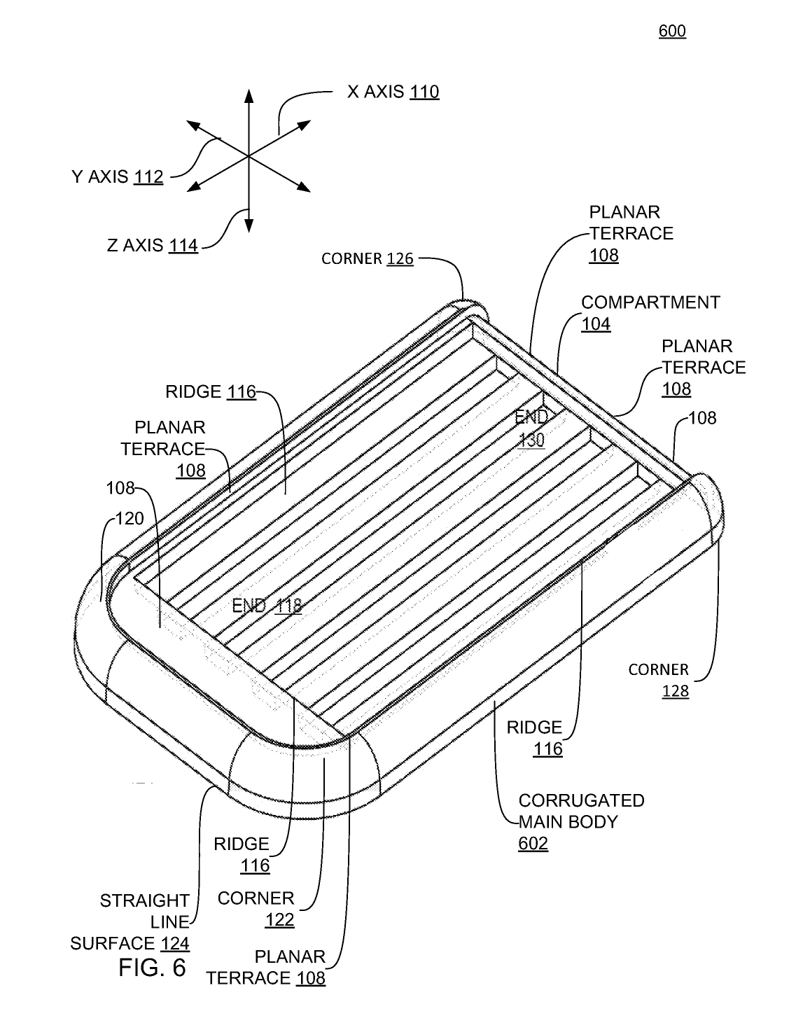

FIG. 5 is an isometric cross-section diagram of a top/side view of a solar canopy without a top cover, with a bottom cover and having a solar panel, according to an implementation. Solar canopy 100 includes a main body 106. Along a first end 118 of the main body 106 of the solar canopy 100, the corner 120 of the main body 106 is rounded. In some implementations, the corner 120 is rounded with a greater radius than shown in FIG. 5 to the extent that there is no straight line surface 124 between the rounded corners 122 (shown in FIGS. 2) and 120 in which the rounded corner 122 (shown in FIGS. 2) and 120 merge into one continuously rounded hemispheric half-circular corner. Some implementations of the main body 106 the solar canopy 100 also includes rounded corner 128 on the opposite end 130 from end 118. Solar canopy 100 also includes an opening 202.

FIG. 6 is an isometric diagram of a top/front/side view of a solar canopy 600 without a solar panel, without a top cover and having a corrugated main body, according to an implementation.

Solar canopy 600 includes a corrugated main body 602 having a compartment 104. In some implementations, a solar panel (not shown in FIG . 6, such as solar panel 102 in FIG. 1) could be removeably attached to one or more interior surfaces of the compartment 104 using an apparatus such as screws, a hook-and-loop apparatus such as Velcro®, or nuts and bolts. In other implementations, the solar panel 102 (not shown in FIG. 6) would not be attached to any of the interior surfaces of the compartment 104 in which the solar panel 102 is held in place by the operation of gravity upon the solar panel 102 when the solar canopy 600 would be positioned in an up/down orientation such as shown in FIG. 1. The compartment 104 is a recessed area within the main body that in some implementations is enclosed on five sides of the compartment 104 and in which one side is open that allows the solar panel 102 to be placed within the compartment 104 and when the solar panel 102 is not attached or removeably attached w/in the compartment 104 the solar panel 102 could be removed from the compartment 104 through the open side of the compartment 104.

The corrugated main body 602 of the solar canopy 600 also includes a planar terrace 108. The function of the planar terrace 108 is to receive a planar cover (not shown) that contacts the planar terrace 108 along all or substantially all of the planar terrace 108 and that provides support and stability to the planar cover along an X axis 110 and an Y axis 112 that inhibits movement of the solar canopy along a Z axis 114.

The solar panel 102 could be positioned within the compartment 104 parallel to the planar terrace 108 along the Z axis 114 and the solar panel 102 is positioned at a different position to the compartment 104 along the Z axis 114. The compartment 104 is a recess to the planar terrace 108.

In some implementations, the corrugated main body 602 of the solar panel 102 also includes a lip or a ridge 116 at the outer perimeter of the planar terrace 108. The ridge inhibits movement of a cover along the X axis 110 and the Y axis 112. The ridge 116 is open on one side (the top side) that allows the solar panel 102 to be placed in and removed from the corrugated main body 602 of the solar canopy 600.

Along a first end 118 of the corrugated main body 602 of the solar canopy 600, the corners 120 and 122 of the corrugated main body 602 are rounded. In some implementations, the corners 120 and 122 are rounded with a greater radius than shown in FIG. 1 to the extent that there is no straight line surface 124 between the rounded corners 120 and 122 in which the two rounded corners 120 and 122 merge into one continuously rounded hemispheric half-circular corner. Some implementations of the corrugated main body 602 the solar canopy 600 also includes rounded corners 126 and 128 on the opposite end 130 from end 118. While the solar canopy 600 is not limited to any particular solar panel 102, a compartment 104, a corrugated main body 602, a planar terrace 108, an X axis 110, an Y axis 112, a Z axis 114, a lip or a ridge 116, a first end 118 of the corrugated main body 602, corners 120 and 122 of the corrugated main body 602, a straight line surface 124, rounded corners 126 and 128 on the opposite end 130, for sake of clarity a simplified solar panel, a compartment 104, a corrugated main body 602, a planar terrace 108, an X axis 110, an Y axis 112, a Z axis 114, a lip or a ridge 116, a first end 118 of the corrugated main body 602, corners 120 and 122 of the corrugated main body 602, a straight line surface 124, rounded corners 126 and 128 on the opposite end 130 are described.

The corrugated main body 602 provides strength along the longitudinal axis of the main body, provides space for wires and also provides a drainage for precipitation and other liquids.

A vertical wall of corrugated main body has holes through the wall at the bottom portion of the corrugation in order to allow water to flow out of the bottom the corrugation.

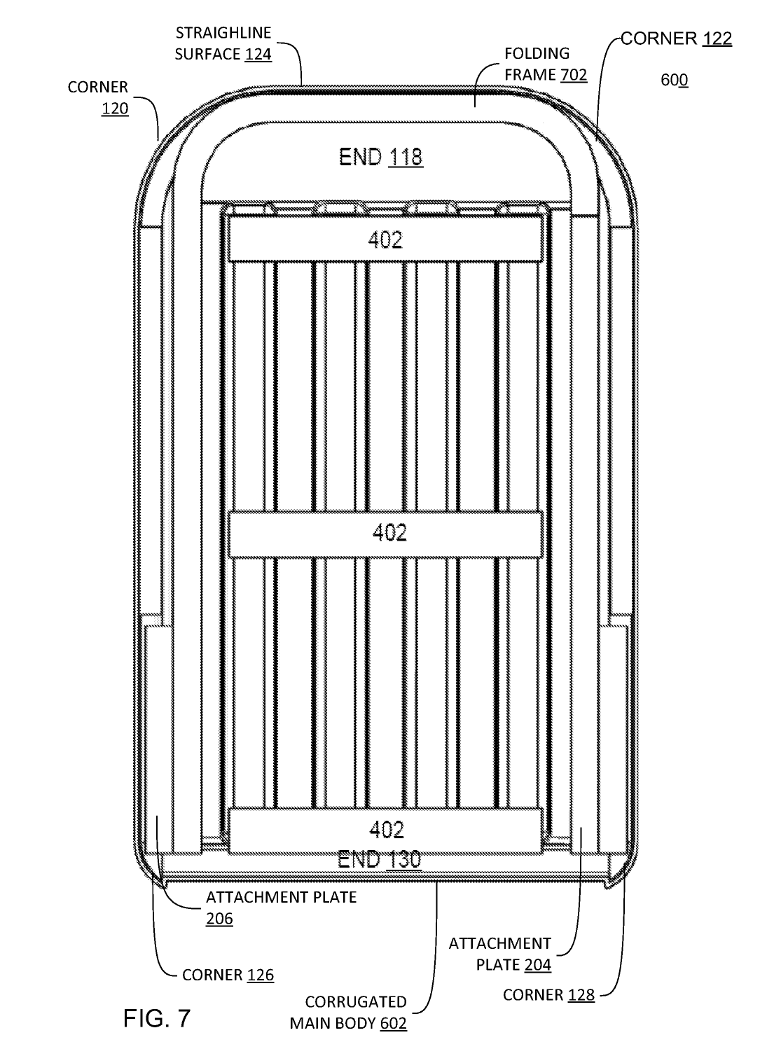

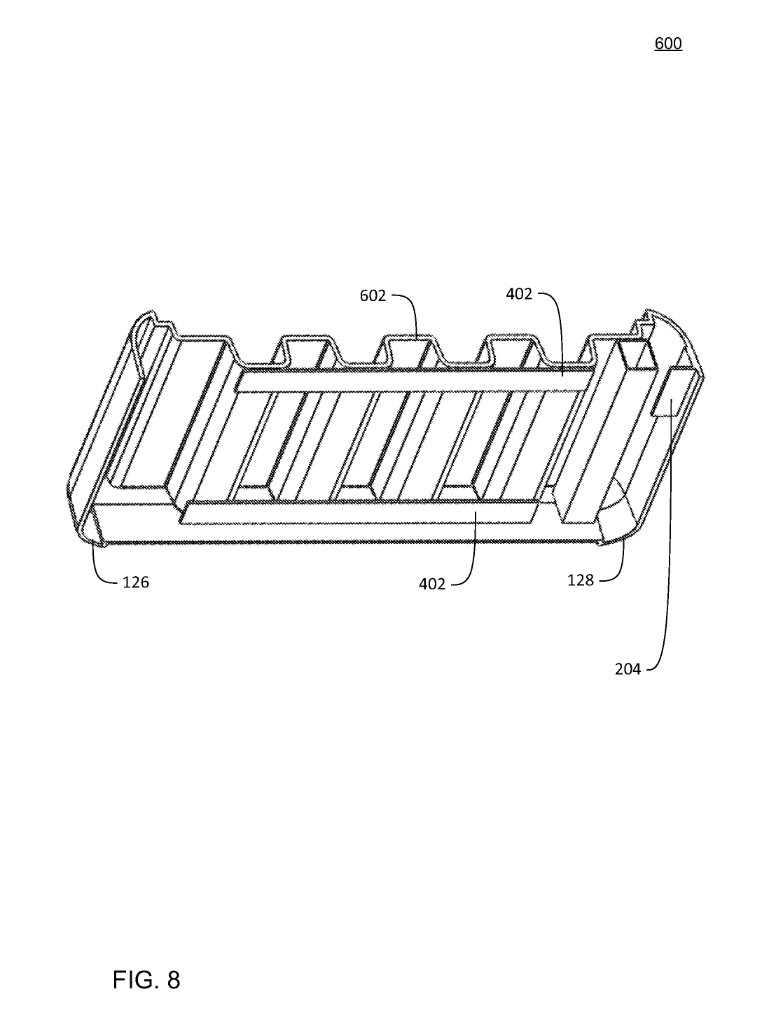

FIG. 7 is a diagram of a bottom view of a solar canopy without a bottom cover and having a corrugated main body with bottom cover attachment plates and frame attachment plates, according to an implementation. Along a first end 118 of the corrugated main body 602 of the solar canopy 600, the corners 120 and 122 of the corrugated main body 602 are rounded. In some implementations, the corners 120 and 122 are rounded with a greater radius than shown in FIG. 7 to the extent that there is no straight line surface 124 between the rounded corners 120 and 122 in which the two rounded corners 120 and 122 merge into one continuously rounded hemispheric half-circular corner. In some implementations of the corrugated main body 602, the solar canopy 600 also includes rounded corners 126 and 128 on the opposite end 130 from end 118. Solar canopy 600 includes a folding frame 702 that is rotably attached to the main body 602. The folding frame 702 has a U geometry. The folding frame 702 is rotatable to a right-angle position relative to the position shown in FIG. 7, whereupon the frame 702 can be attached to a motorized wheelchair, according to an implementation. Frame attachment plates 204 and 206 operably couple a folding frame (shown in FIG. 13-22) to the main body 602. Bottom cover attachment plates 402 are operable to fixedly attach the bottom of the main body 602 to a bottom cover (not shown).

FIG. 8 is an isometric cross-section diagram of a bottom/side view of a solar canopy 600 without a top cover, without a bottom cover, without a solar panel and having a corrugated main body with bottom cover attachment plates and frame attachment plate, according to an implementation. Solar canopy 600 includes a corrugated main body 602. The first end 118 of the corrugated main body 602 of the solar canopy 600 is not shown in FIG. 8. In some implementations of the solar canopy 600, the corrugated main body 602 also includes rounded corners 126 and 128 on the opposite end 130 from end 118. Frame attachment plate 204 operably couples a folding frame (shown in FIG. 13-22) to the main body 602. Bottom cover attachment plates 402 are operable to fixedly attach the bottom of the main body 602 to a bottom cover (not shown).

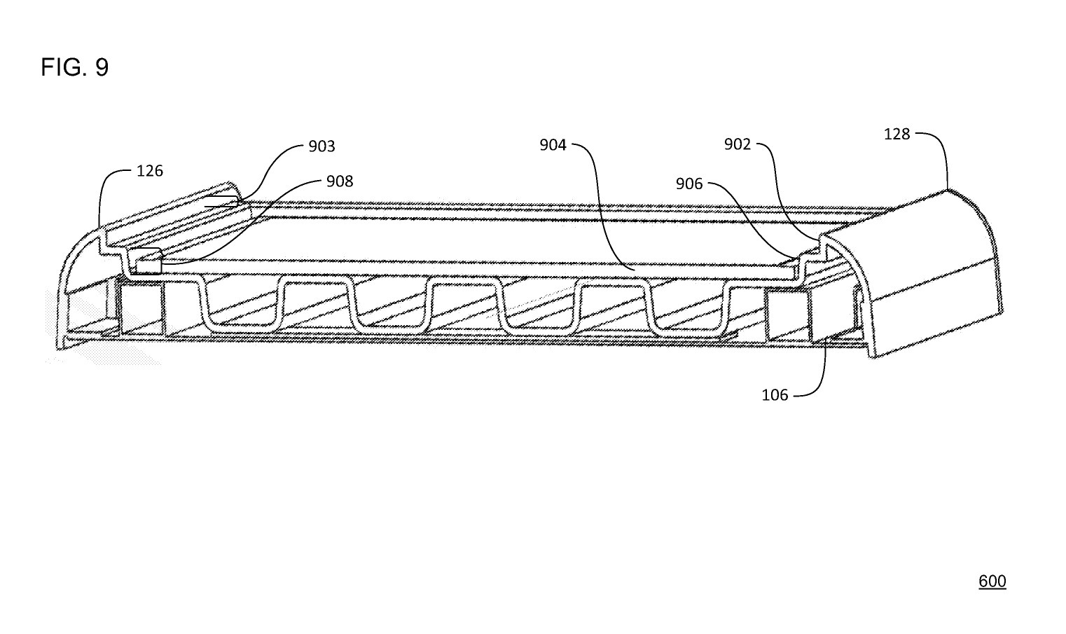

FIG. 9 is an isometric cross-section diagram of a side view of a solar canopy 600 without a top cover, with a bottom cover, having a solar panel and having a corrugated main body, according to an implementation. The first end 118 of the corrugated main body 602 of the solar canopy 600 is not shown in FIG. 8. In some implementations of the solar canopy 600, the corrugated main body 602 also includes rounded corners 126 and 128 on the opposite end 130 from end 118.

The corrugated main body 602 has a first recess 902. The first recess 902 of the corrugated main body 602 has an interior length, an interior width and an interior depth 903. In some implementations, such as shown in FIG. 9, the first recess 902 of the interior length is at least 20 times the interior depth. The first recess 902 has a corrugated surface. The corrugated first recess 902 provides strength along the longitudinal axis of the main body 602, provides space for wires between the two ends 118 and 130 of the main body 602 and also provides drainage channels for precipitation and other liquids.

The corrugated main body 602 has an electrical source 904, such as the solar panel shown in FIG. 9. The electrical source 904 is in the first recess 902 of the main body 602. The electrical source 904 has an exterior length, an exterior width and an exterior depth. In some implementations, such as shown in FIG. 9, the exterior length of the electrical source 904 is at least 20 times the exterior depth of the electrical source 904. In some implementations, such as shown in FIG. 9, the exterior depth of the electrical source 904 is about the same as the interior depth 903 of the first recess 902 of the main body 602 which fits the solar panel into the first recess 902.

The corrugated main body 602 has a second recess 906. In some implementations, such as shown in FIG. 9, the second recess 906 is concentric to the first recess 902. The second recess 906 is located on the exterior of the main body 602 and the first recess 902 is located inward from the second recess 906 and the exterior of the main body 602. The second recess 906 has an interior length, an interior width and an interior depth 908.

Some implementations solar canopy 600 includes a top cover in the second recess 906. The top cover has an exterior length, an exterior width and an exterior depth, the exterior length of the top cover being about the same as the interior depth 908 of the second recess 906 and the exterior width of the top cover being about the same as the interior width of the second recess 906 which fits the top cover into the second recess 906.

In some implementations, the top cover is a translucent sheet. In some implementations, the translucent sheet is clear plastic. The clear plastic top cover protects the electrical source from mechanical impact which is particularly helpful where the electrical source is a solar panel because solar panels are delicate and easily harmed by mechanical impact. In some implementations, the clear plastic cover has a dome geometry in which the center of the clear plastic cover is thicker in the center than along the periphery of the clear plastic cover that magnifies solar energy that is received by the solar panel. The dome geometry clear plastic top cover magnifies solar energy because the solar energy is collected from a higher incidence through a lens-effect. The dome geometry clear plastic top cover also has the effect of more effectively drawing rain water and melted snow towards the periphery of the dome geometry clear plastic top cover and away from the solar panel.

In some implementations, the electrical power source 904 is electrically coupled to a battery and the battery is electrically coupled to a drive motor of a motorized wheelchair.

The main body 602 does have reverse draft in the corrugated portion in order to be suitable for vacu-form molding. The corrugated portion of a mold perpendicular to a parting line requires taper or draft to permit proper ejection from the mold. The taper of draft allows the part to break free by creating a clearance as soon as the mold starts to open. Since thermoplastics shrink during cooling, the thermoplastic grips to cores or male forms in the mold making normal ejection difficult if draft is not included in the geometry. Side action is eliminated and tool and maintenance costs are reduced. For untextured surfaces generally a minimum of 0.5 degree draft per side is recommended although there are exceptions when less may be acceptable. Polishing in draw line or using special surface treatments can help achieve this. For textured sidewalls use an additional 0.4 degree draft per 0.1 mm depth of texture. Typically 1 to 3 degree of negative draft is optimal. As the draft increases ejection becomes easier but it increases the risk that some sections may become too heavy. Typically 1 to 3 degree draft is recommended. As the draft increases ejection from the mold becomes easier but increased draft increases the risk that some sections may become too heavy.

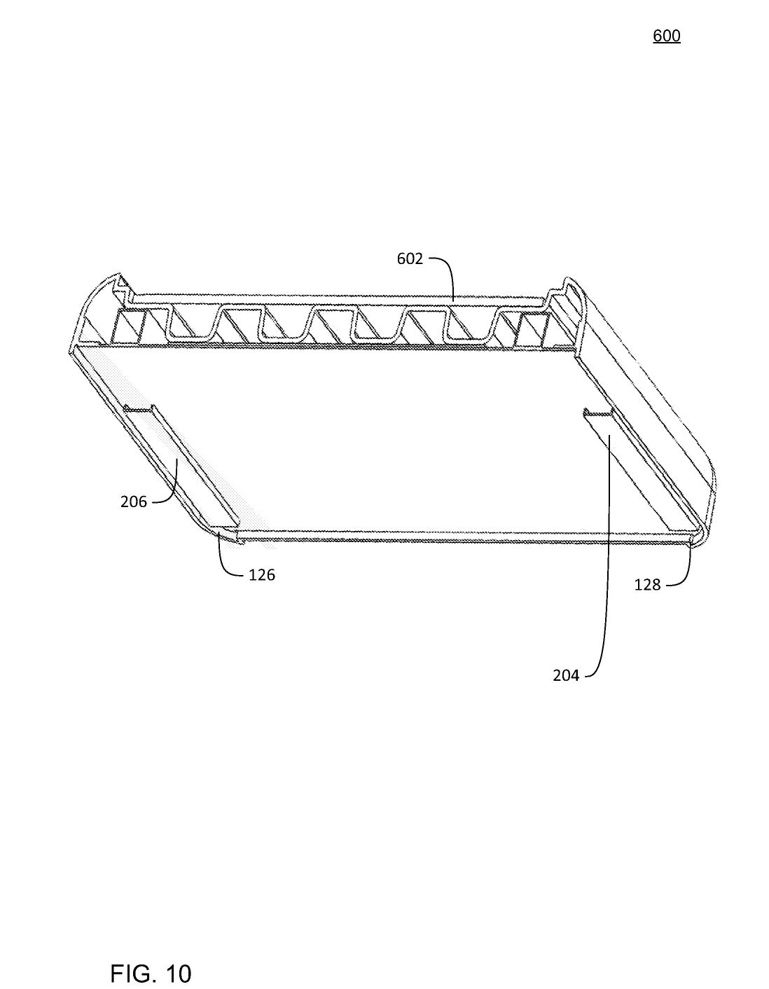

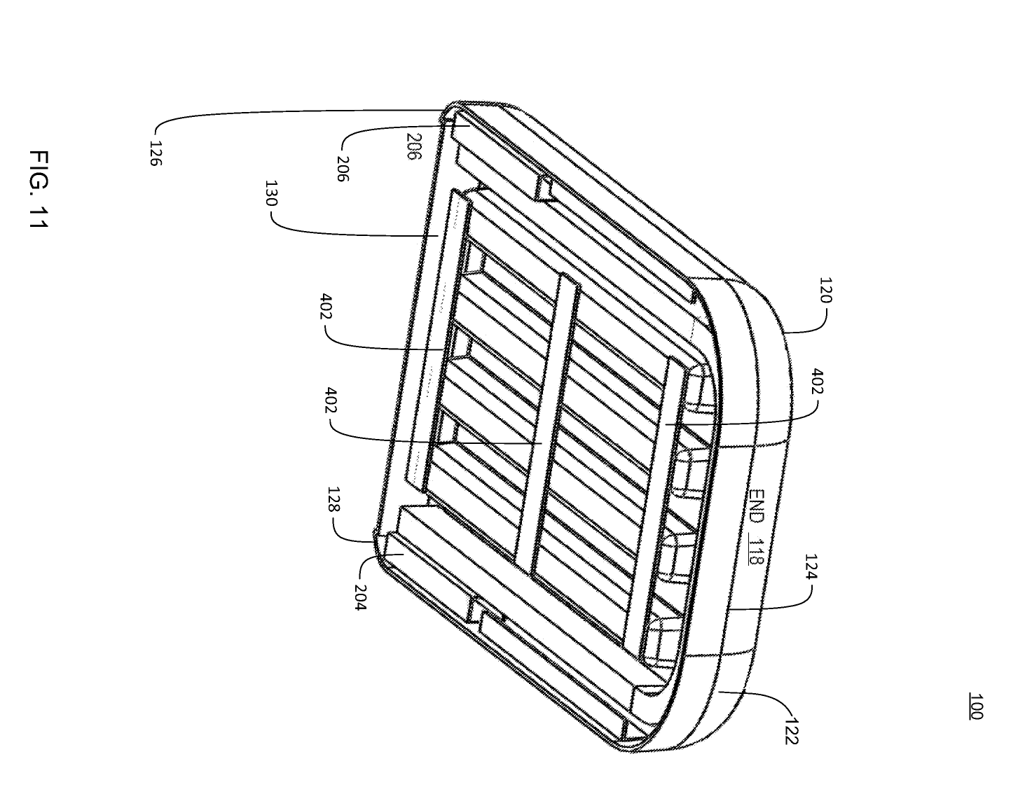

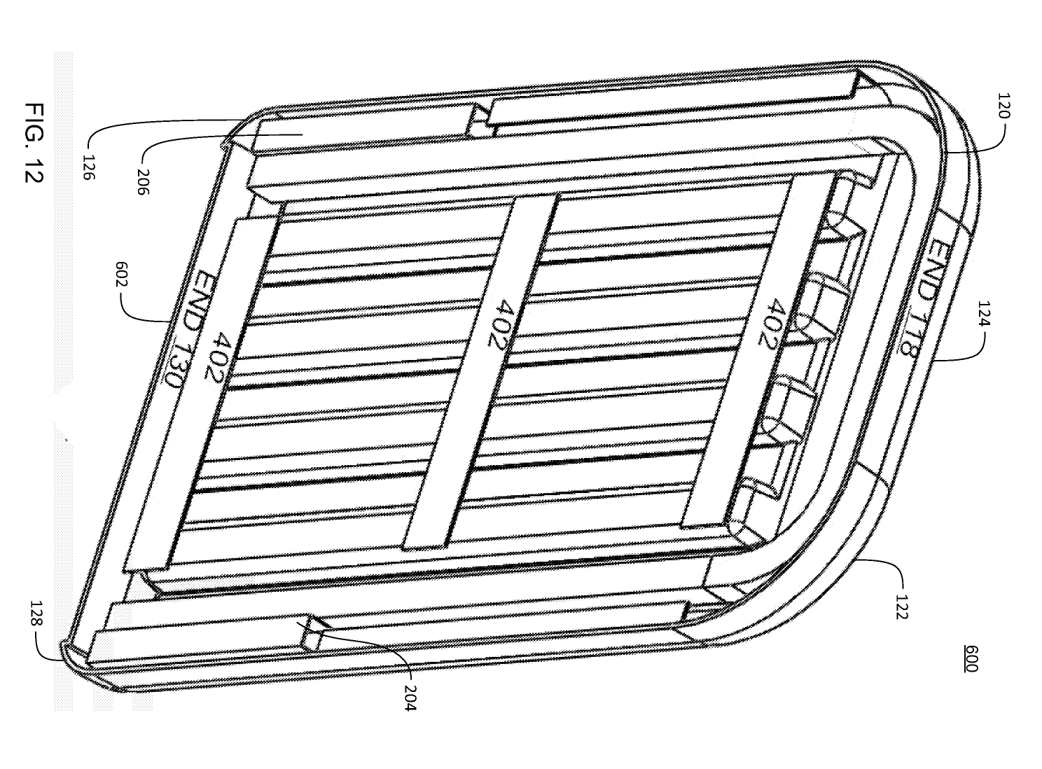

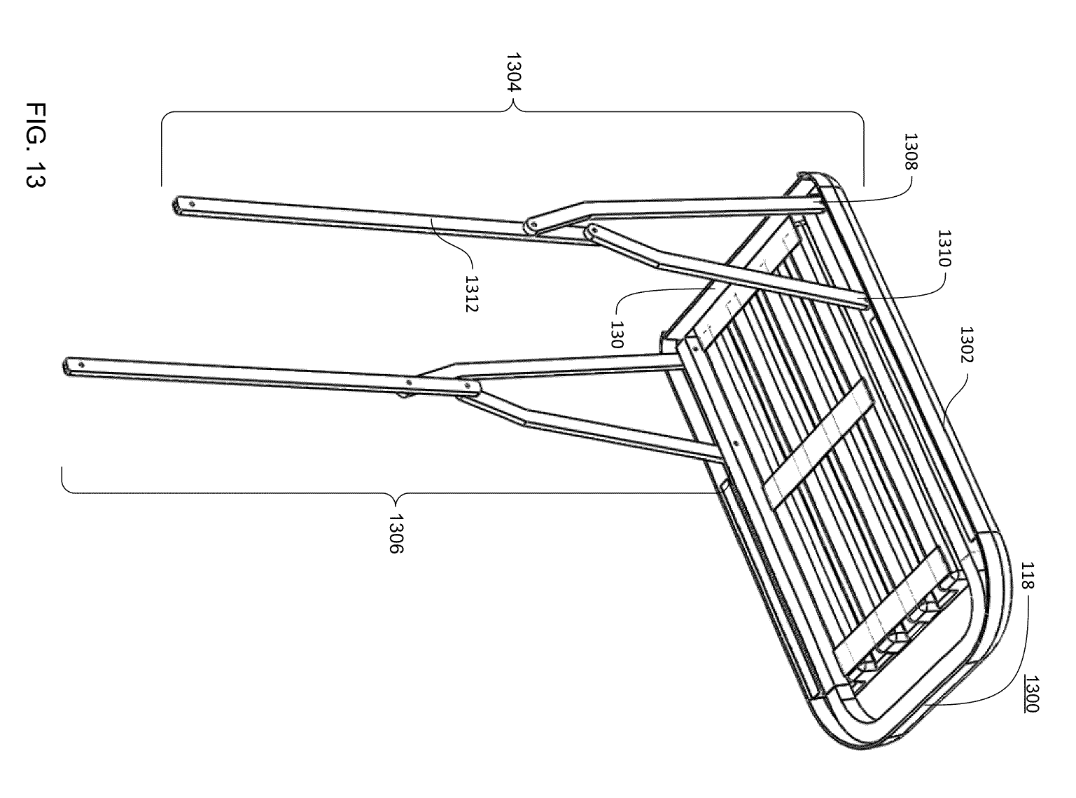

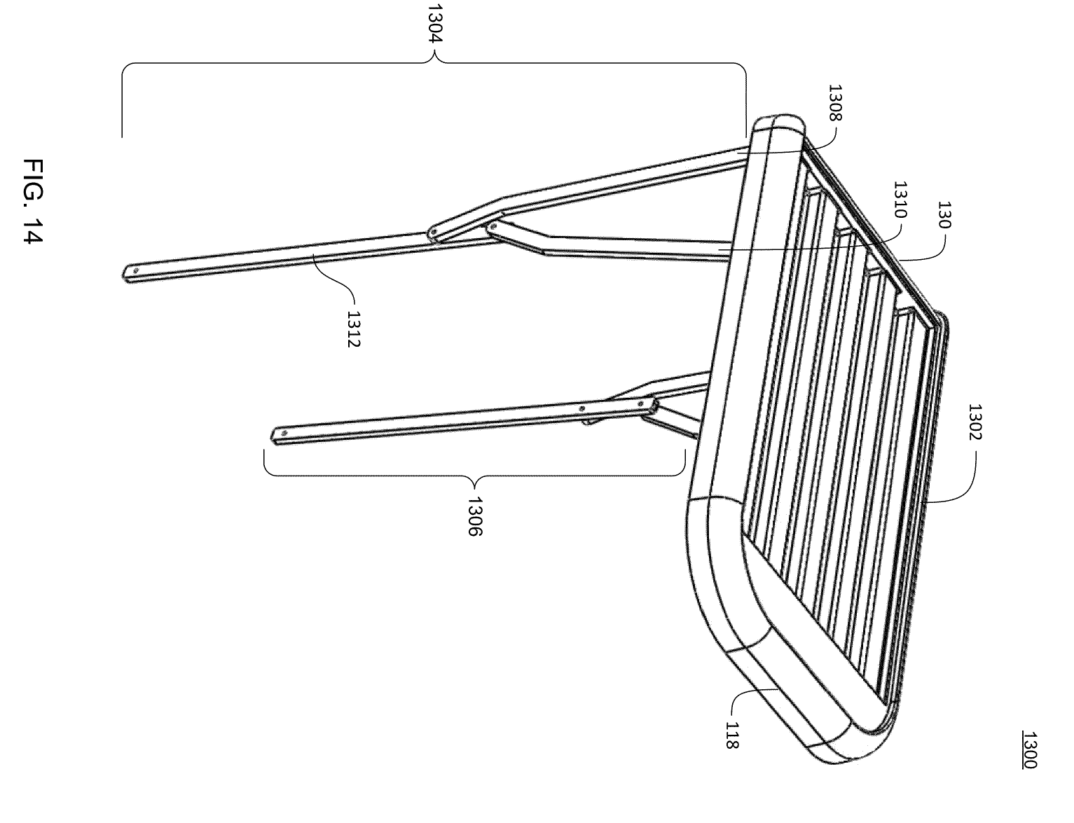

FIG. 10 is an isometric cross-section diagram of a bottom/side view of a solar canopy 600 without a top cover, with a bottom cover, having a solar panel and having a corrugated main body, according to an implementation. Solar canopy 600 includes a corrugated main body 602. The first end 118 of the corrugated main body 602 of the solar canopy 600 is not shown in FIG. 8. In some implementations of the solar canopy 600, the corrugated main body 602 also includes rounded corners 126 and 128 on the opposite end 130 from end 118. Frame attachment plates 204 and 206 operably couple a folding frame (shown in FIG. 13-22) to the main body 602.

FIG. 11 is an isometric diagram of a bottom/side view of a solar canopy 600 without a bottom cover, having a corrugated main body with bottom cover attachment plates and frame attachment plates, according to an implementation. Solar canopy 600 includes a corrugated main body 602. Along a first end 118 of the corrugated main body 602 of the solar canopy 600, the corners 120 and 122 of the corrugated main body 602 are rounded. In some implementations, the corners 120 and 122 are rounded with a greater radius than shown in FIG. 11 to the extent that there is no straight line surface 124 between the rounded corners 120 and 122 in which the two rounded corners 120 and 122 merge into one continuously rounded hemispheric half-circular corner. In some implementations of the corrugated main body 602, the solar canopy 600 also includes rounded corners 126 and 128 on the opposite end 130 from end 118. Frame attachment plates 204 and 206 operably couple a folding frame (shown in FIG. 13-22) to the main body 602. Bottom cover attachment plates 402 are operable to fixedly attach the bottom of the main body 602 to a bottom cover (not shown).

FIG. 12 is an isometric diagram of a bottom/side view of a solar canopy 600 without a bottom cover, having a corrugated main body with bottom cover attachment plates and frame attachment plates, according to an implementation. Along a first end 118 of the corrugated main body 602 of the solar canopy 600, the corners 120 and 122 of the corrugated main body 602 are rounded. In some implementations, the corners 120 and 122 are rounded with a greater radius than shown in FIG. 12 to the extent that there is no straight line surface 124 between the rounded corners 120 and 122 in which the two rounded corners 120 and 122 merge into one continuously rounded hemispheric half-circular corner. In some implementations of the corrugated main body 602, the solar canopy 600 also includes rounded corners 126 and 128 on the opposite end 130 from end 118. Frame attachment plates 204 and 206 operably couple a folding frame (shown in FIG. 13-22) to the main body 602. Bottom cover attachment plates 402 are operable to fixedly attach the bottom of the main body 602 to a bottom cover (not shown).

FIG. 13 is an isometric diagram of a bottom/side view of a solar canopy system 1300 without a bottom cover, and having a folding frame in fully extended position, according to an implementation. The solar canopy system 1300 includes a solar canopy 1302, such as solar canopy 100 in FIG. 1-5 or solar canopy 600 in FIG. 6-12. e In the implementation shown in FIG. 13-22, the solar canopy 1300 is solar canopy 600. The solar canopy system 1300 includes one or more folding frames 1304 and 1306. Folding frames 1304 and 1306 are examples of folding frame 702 in FIG. 7. In the example shown in FIG. 13-22, the folding frames 1304 and 1306 include 3 members that are rotatably attached to each other and to the solar canopy 1302. The first member 1308 of each folding frame (1304 and 1306) is rotatably attached to the solar canopy 1302 towards the end 130. The second member 1310 of each folding frame (1304 and 1306) is rotatably attached to the solar canopy 1302 between the end 130 and the end 118. The third member 1312 of each folding frame (1304 and 1306) is rotatably attached to the first member 1308 and the second member 1310. The second member 1310 is attached to the third member 1312 above where the first member 1308 is attached to the third member 1312. The first member 1308 and the second member 1310 are bent at an angle that is opposite to each other. The bottom portions of the third members 1312 are operable to be fixedly attached to a wheelchair or motorized scooter suitable for physically disabled people.

FIG. 14 is an isometric cross-section diagram of a top/side view of a solar canopy system 1300 without a top cover, without a solar panel and having a folding frame in fully extended position, according to an implementation.

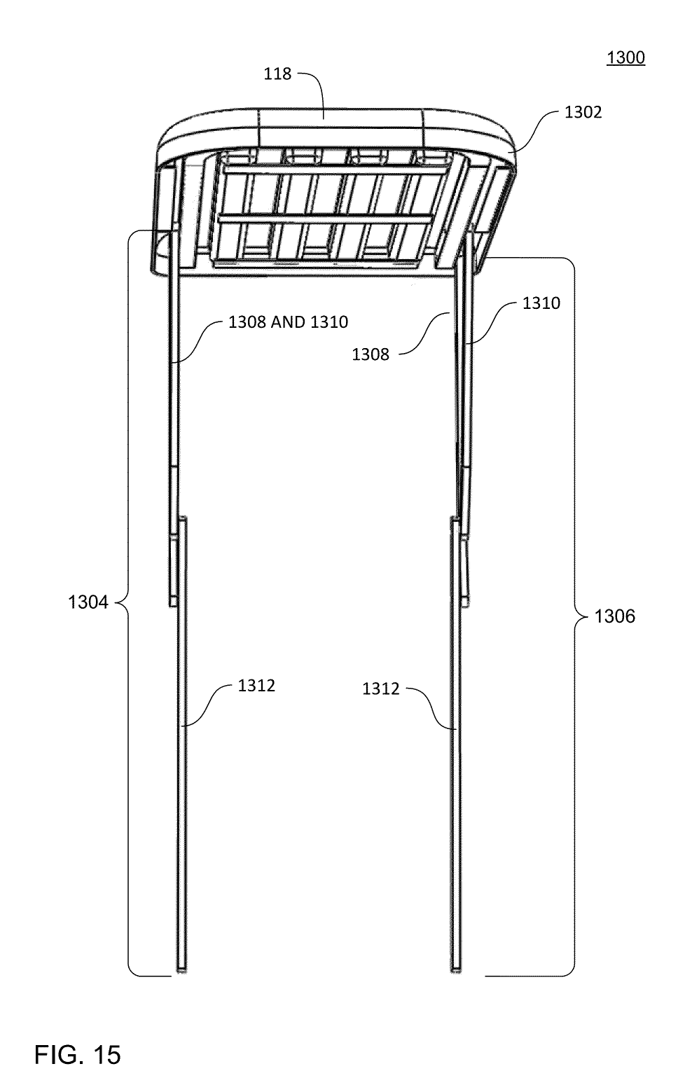

FIG. 15 is an isometric diagram of a bottom/front view of a solar canopy system 1300 without a bottom cover, and having a folding frame in fully extended position, according to an implementation.

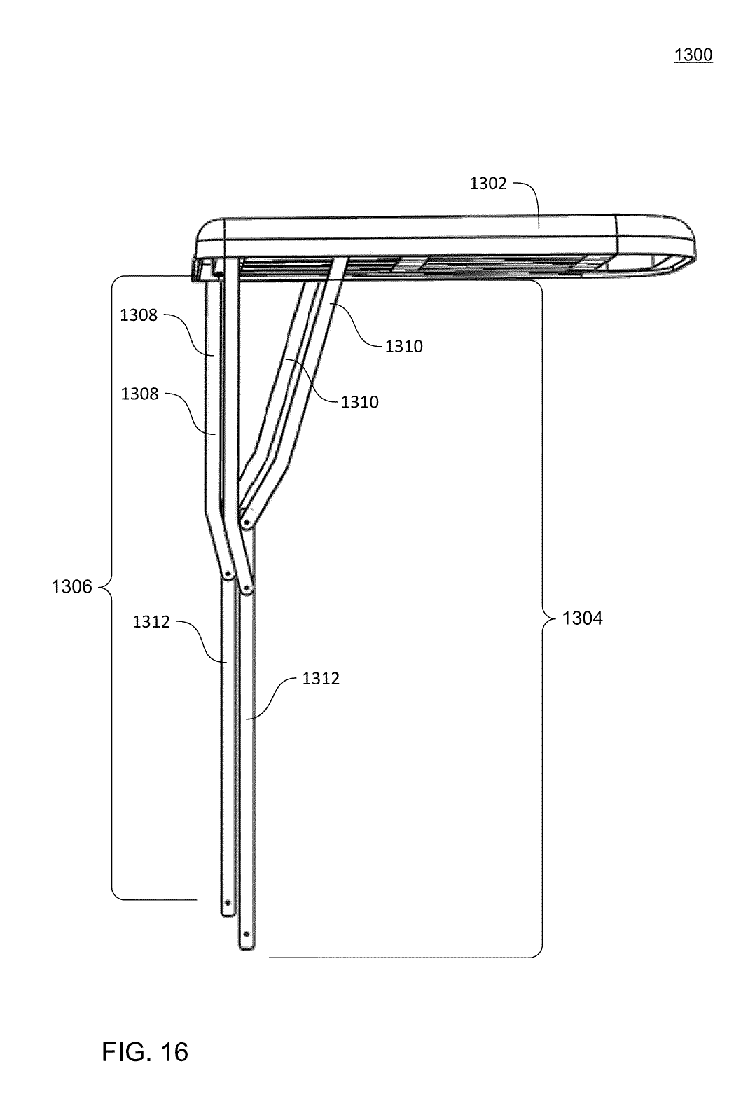

FIG. 16 is an isometric diagram of a bottom/side view of a solar canopy system 1300 without a bottom cover, and having a folding frame in fully extended position, according to an implementation.

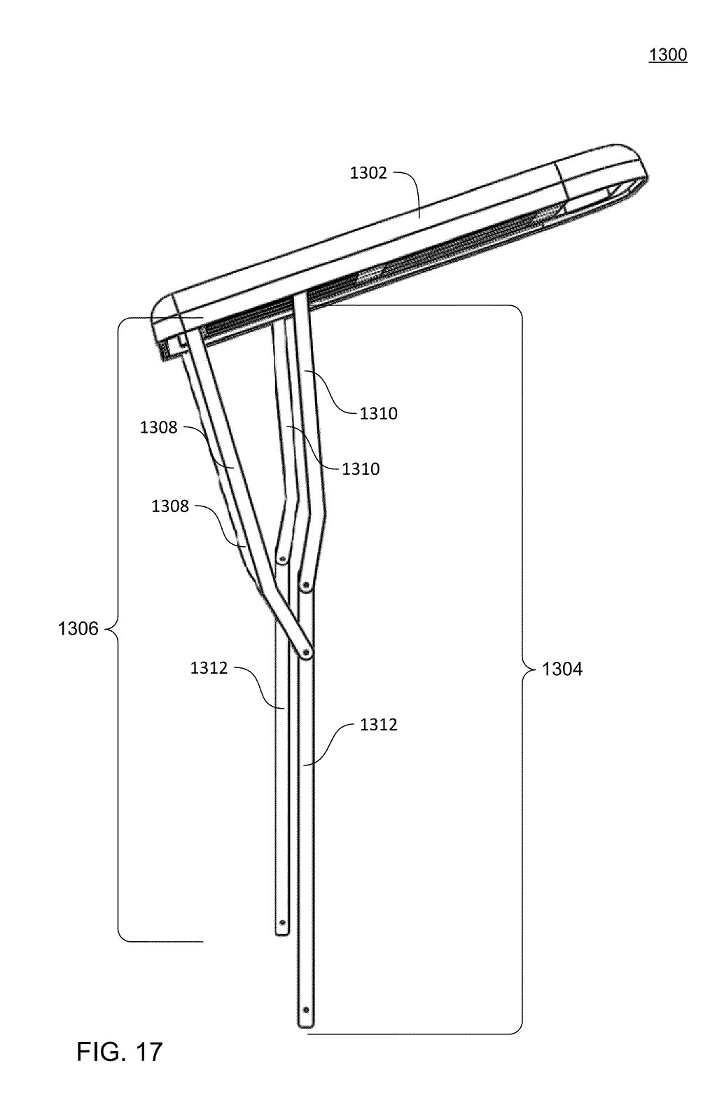

FIG. 17 is an isometric diagram of a bottom/side view of a solar canopy system 1300 without a bottom cover, and having a folding frame in first folded position, according to an implementation.

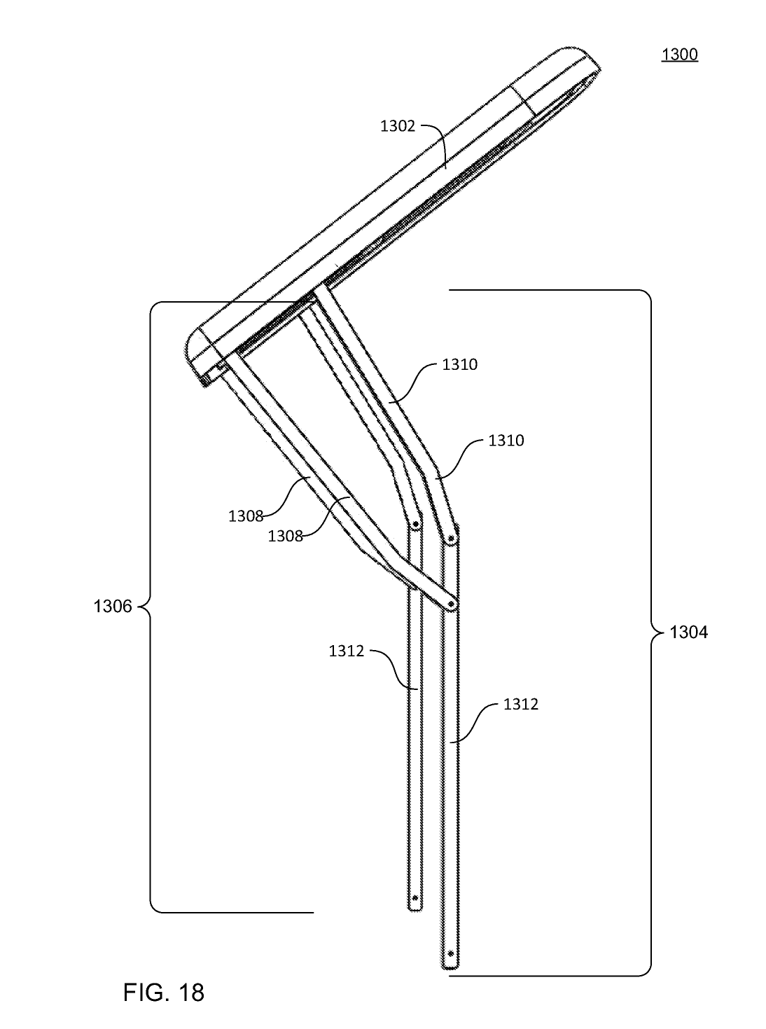

FIG. 18 is an isometric diagram of a bottom/side view of a solar canopy system 1300 without a bottom cover, and having a folding frame in second folded position, according to an implementation.

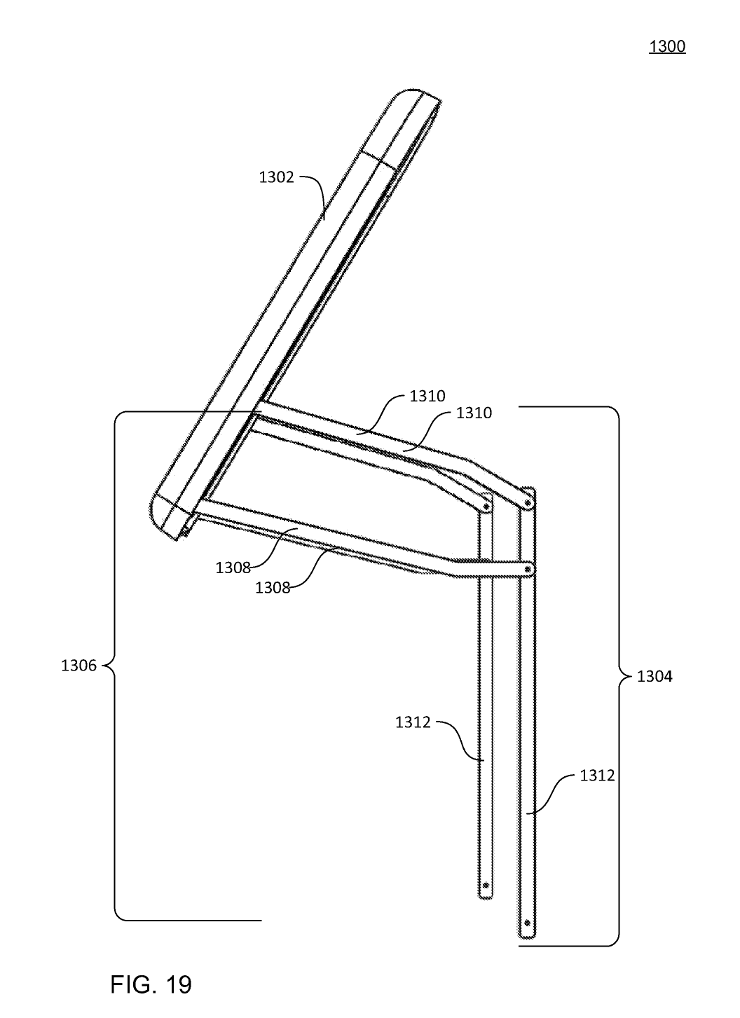

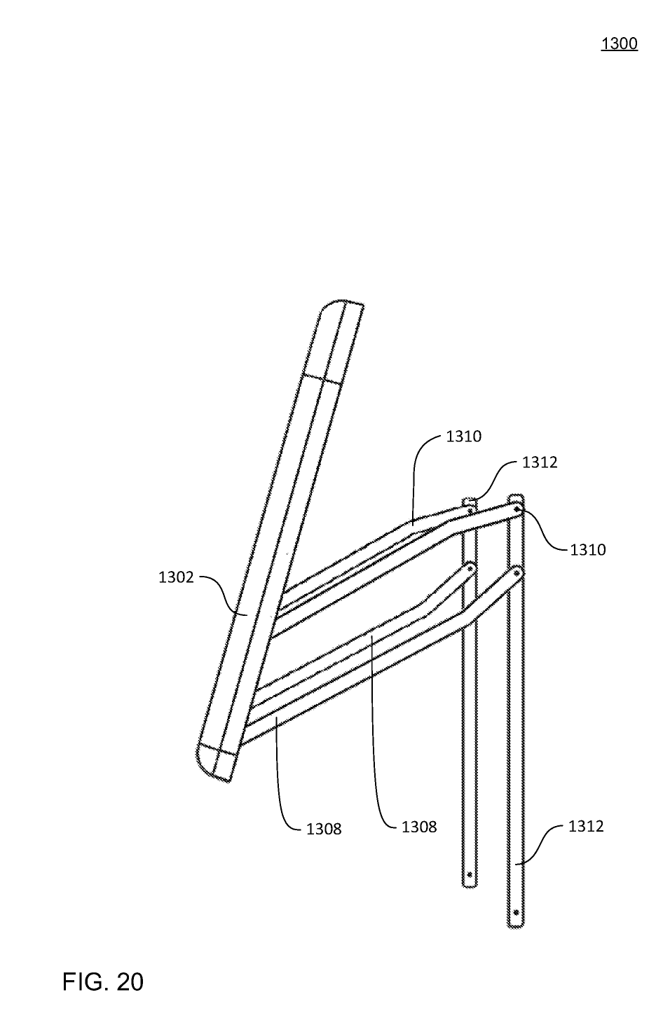

FIG. 19 is an isometric diagram of a bottom/side view of a solar canopy system 1300 without a bottom cover, and having a folding frame in third folded position, according to an implementation.

FIG. 20 is an isometric diagram of a bottom/side view of a solar canopy system 1300 without a bottom cover, and having a folding frame in fourth folded position, according to an implementation.

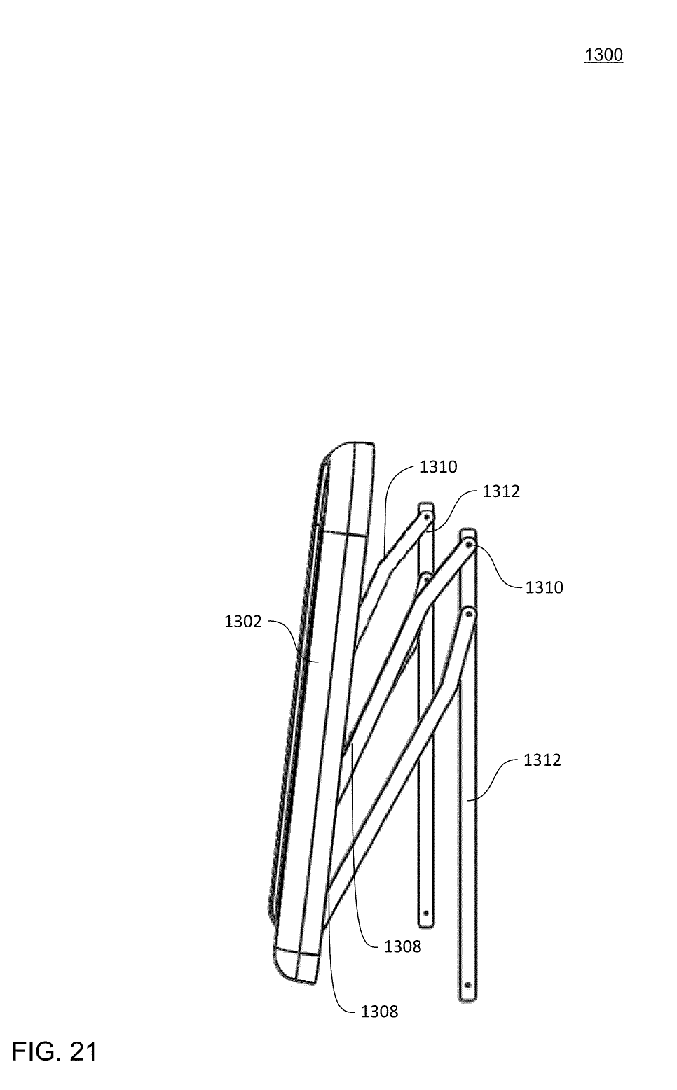

FIG. 21 is an isometric diagram of a bottom/side view of a solar canopy system 1300 without a bottom cover, and having a folding frame in fifth folded position, according to an implementation.

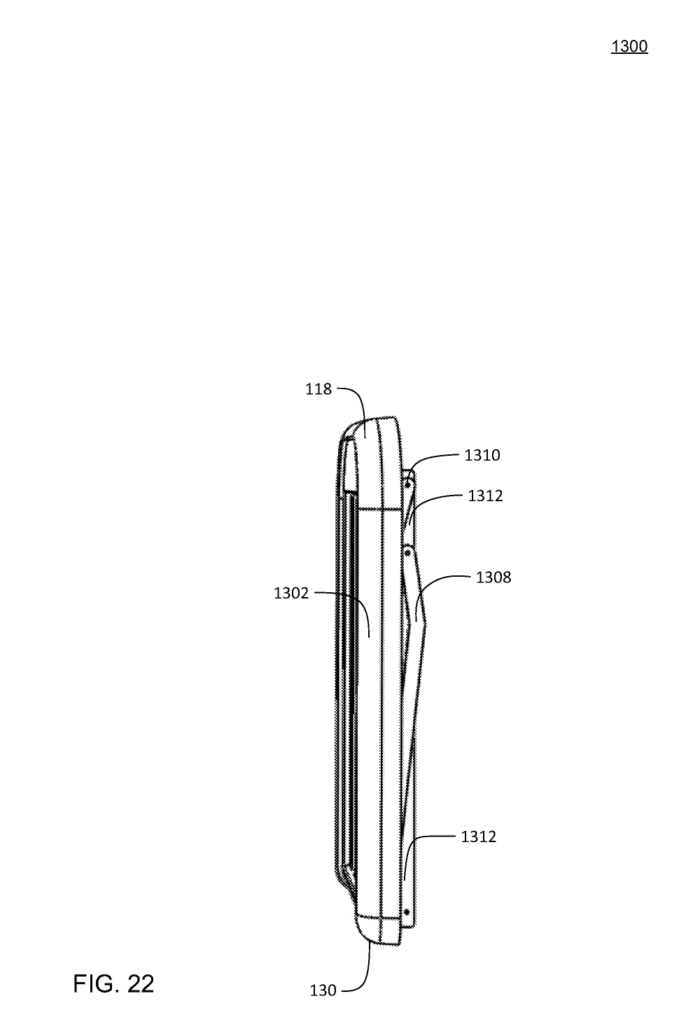

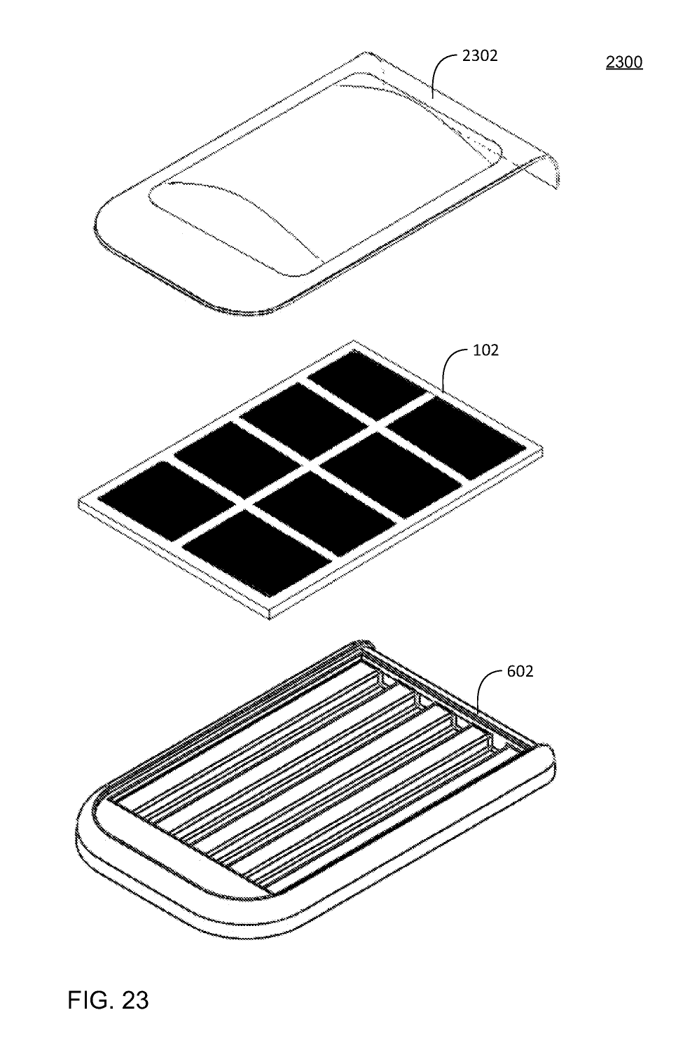

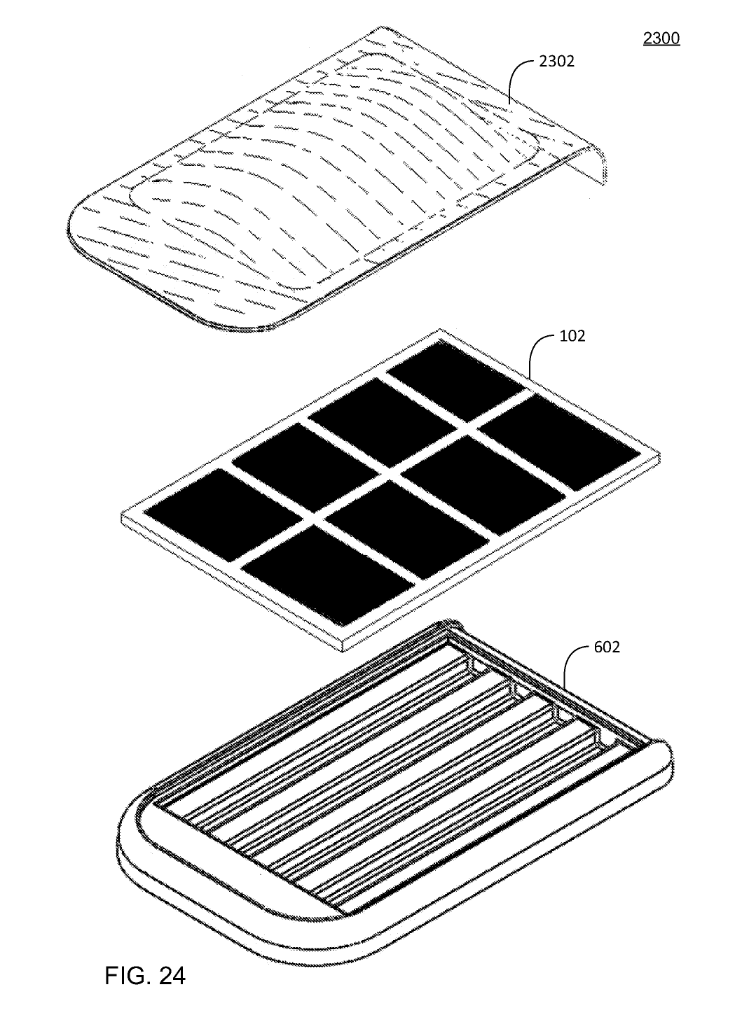

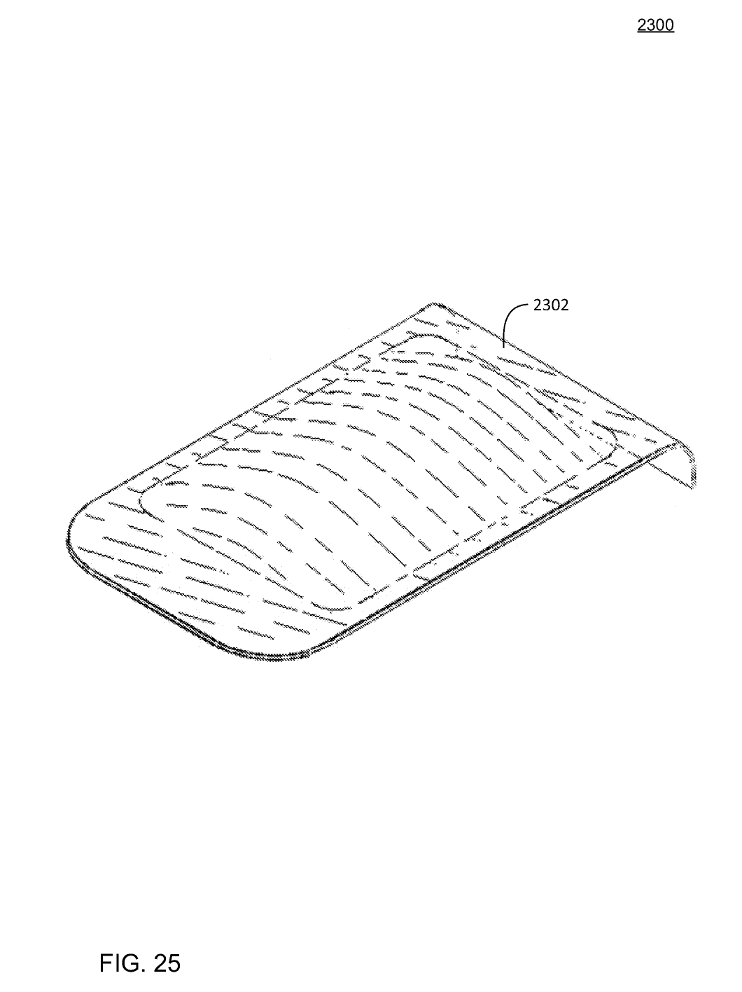

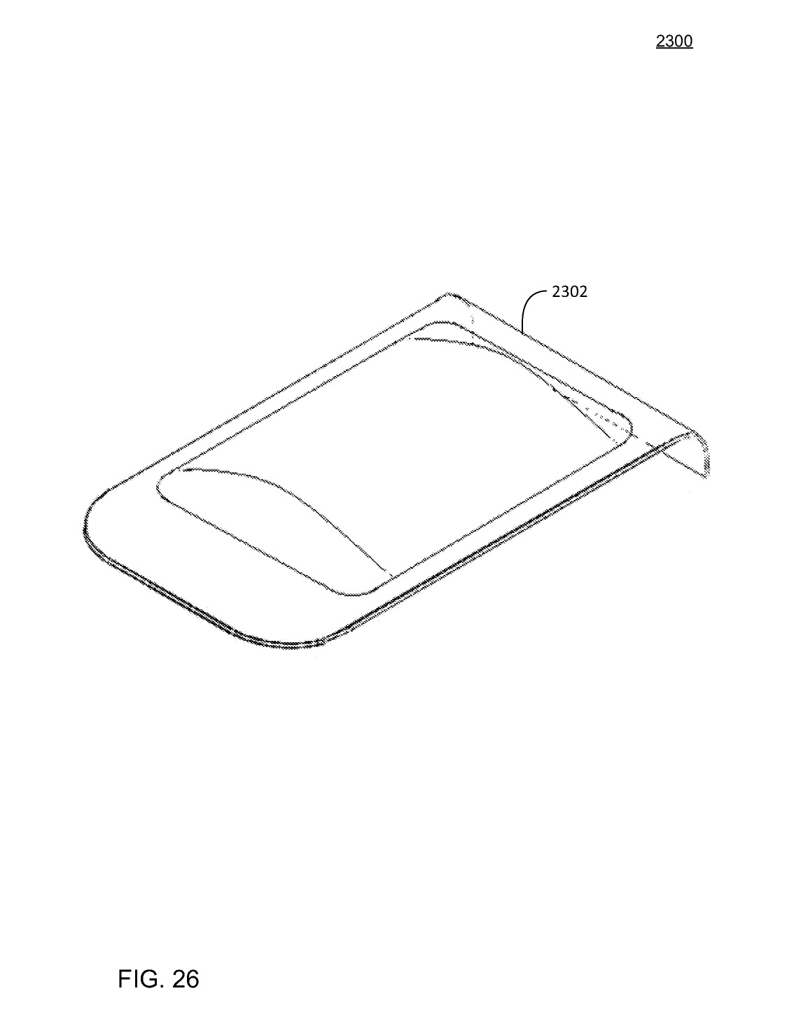

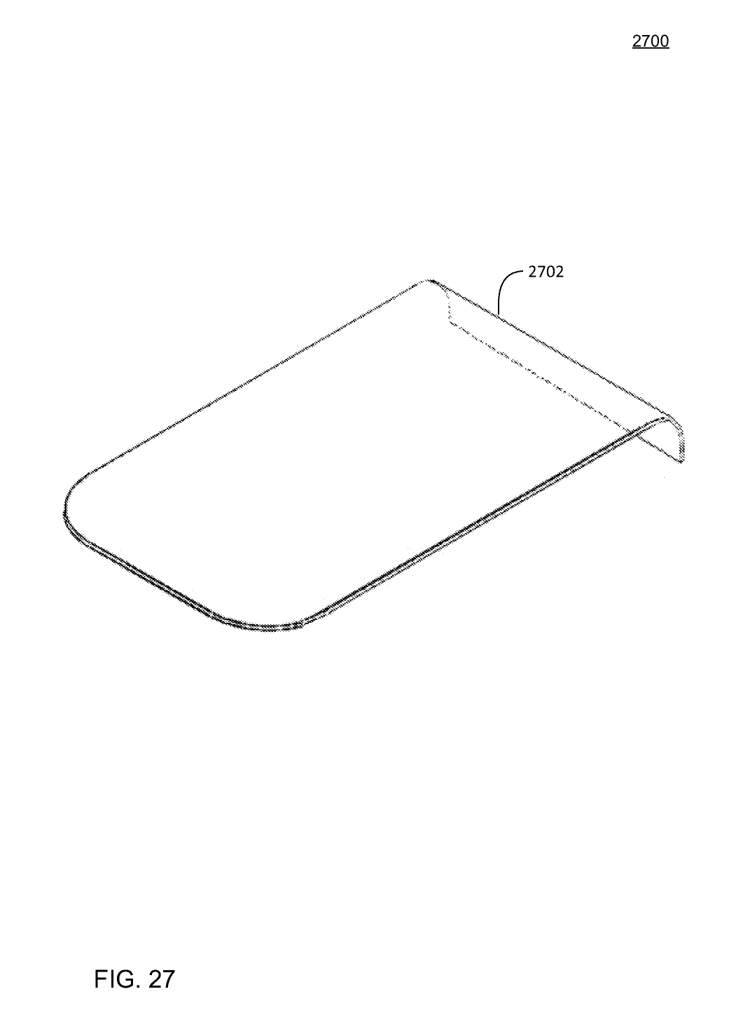

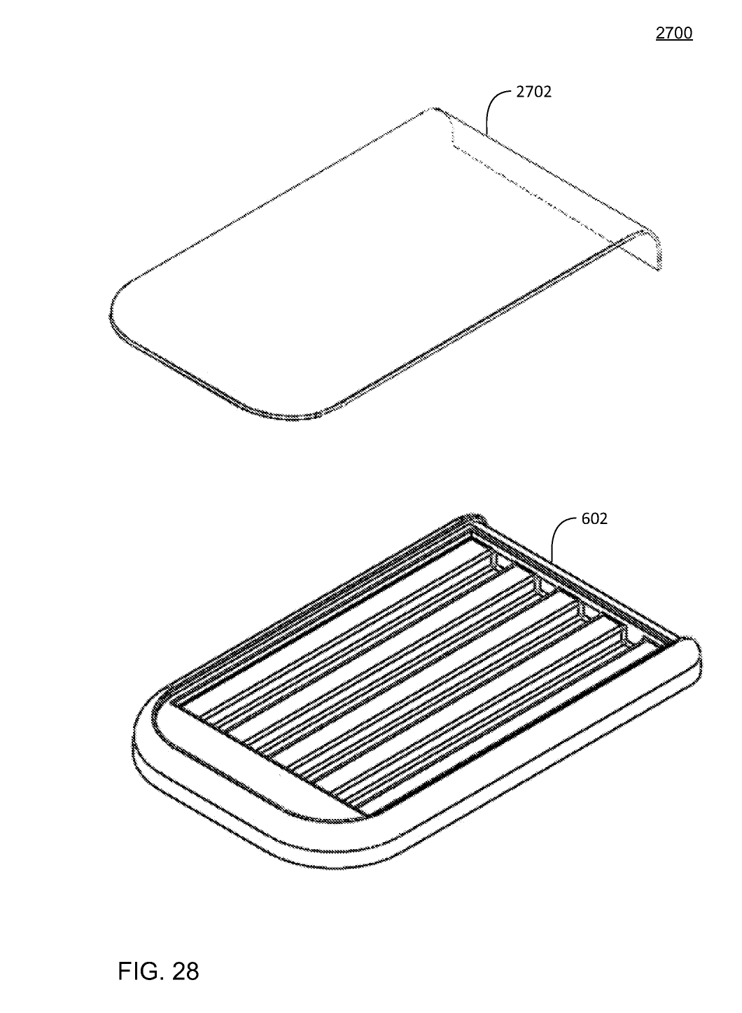

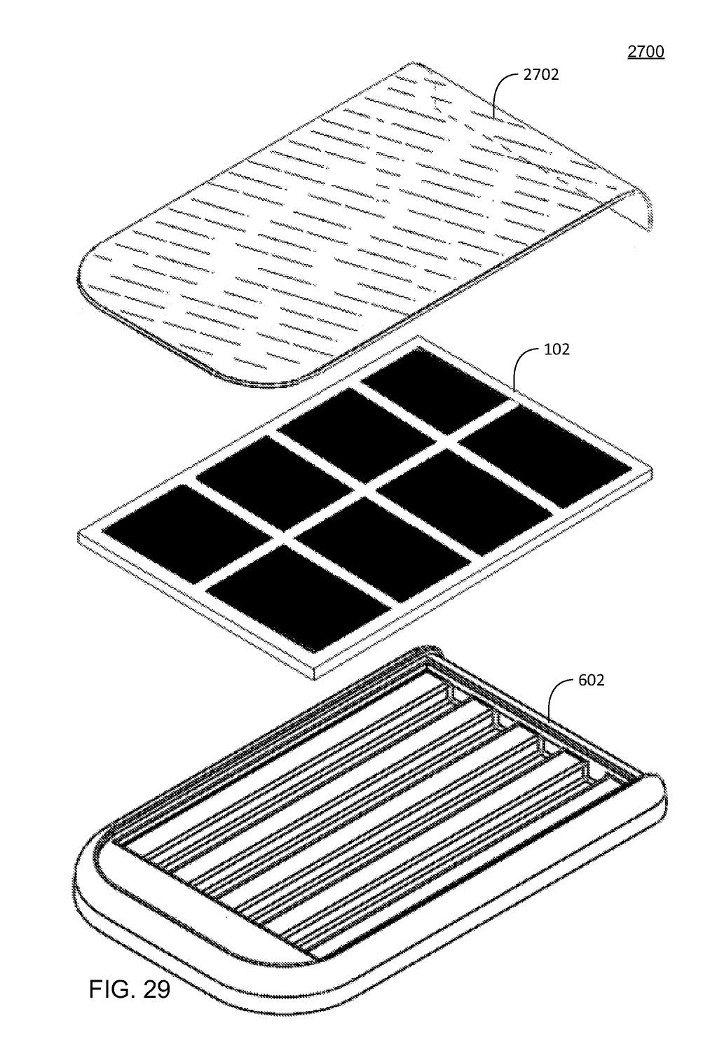

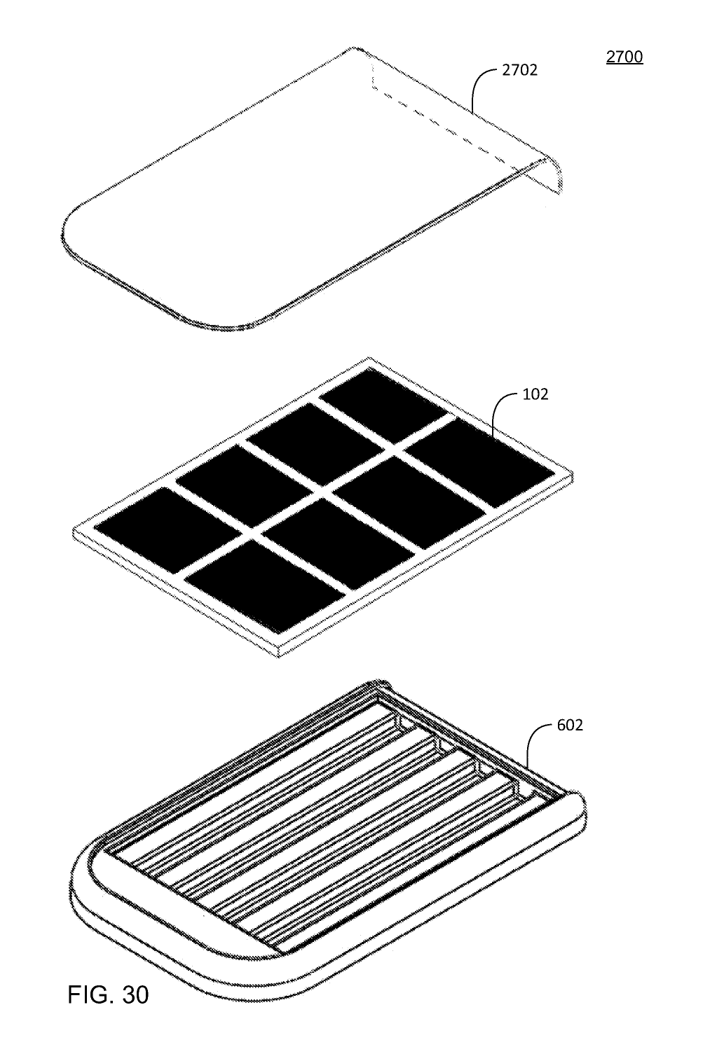

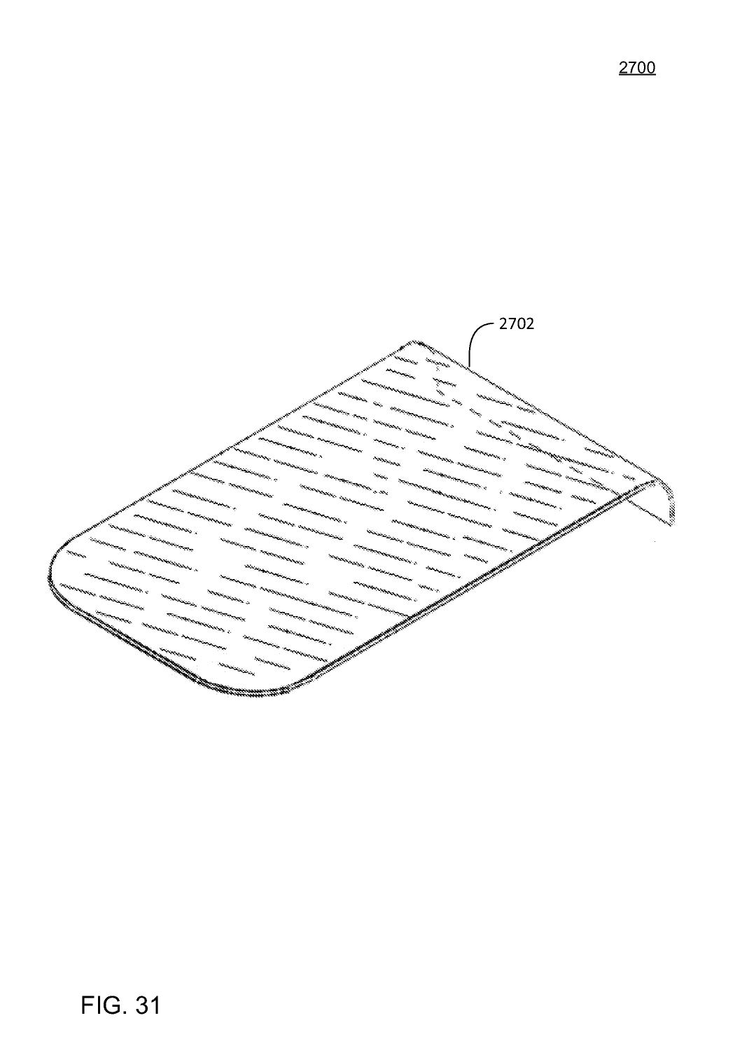

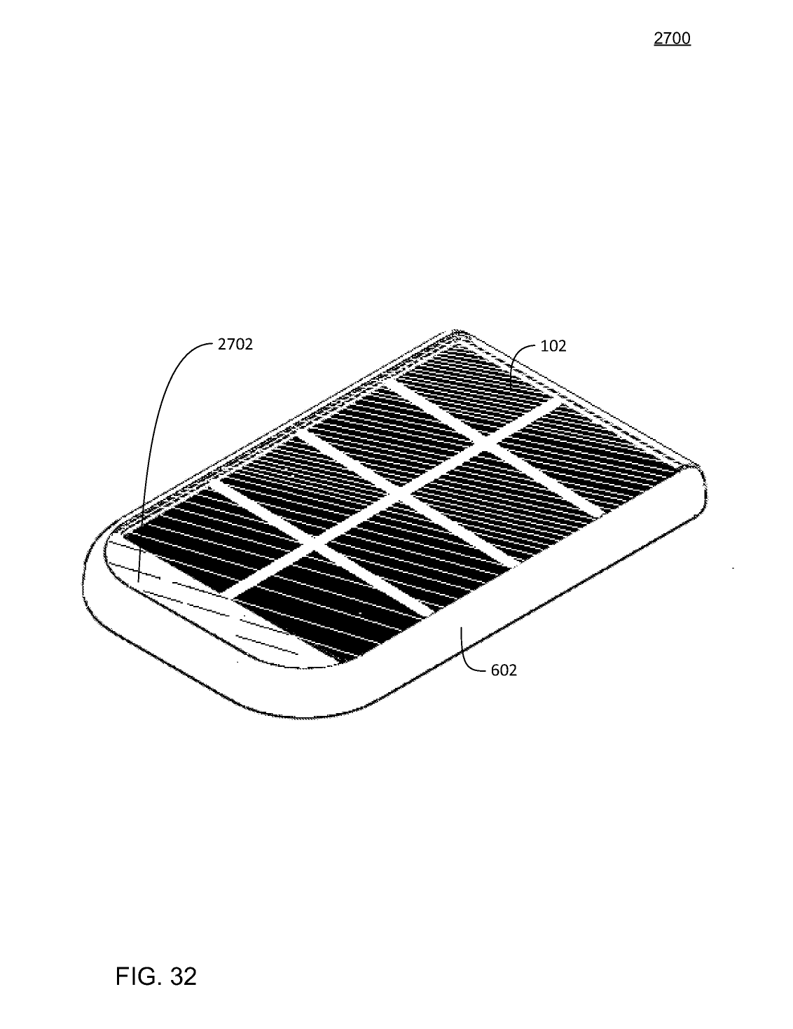

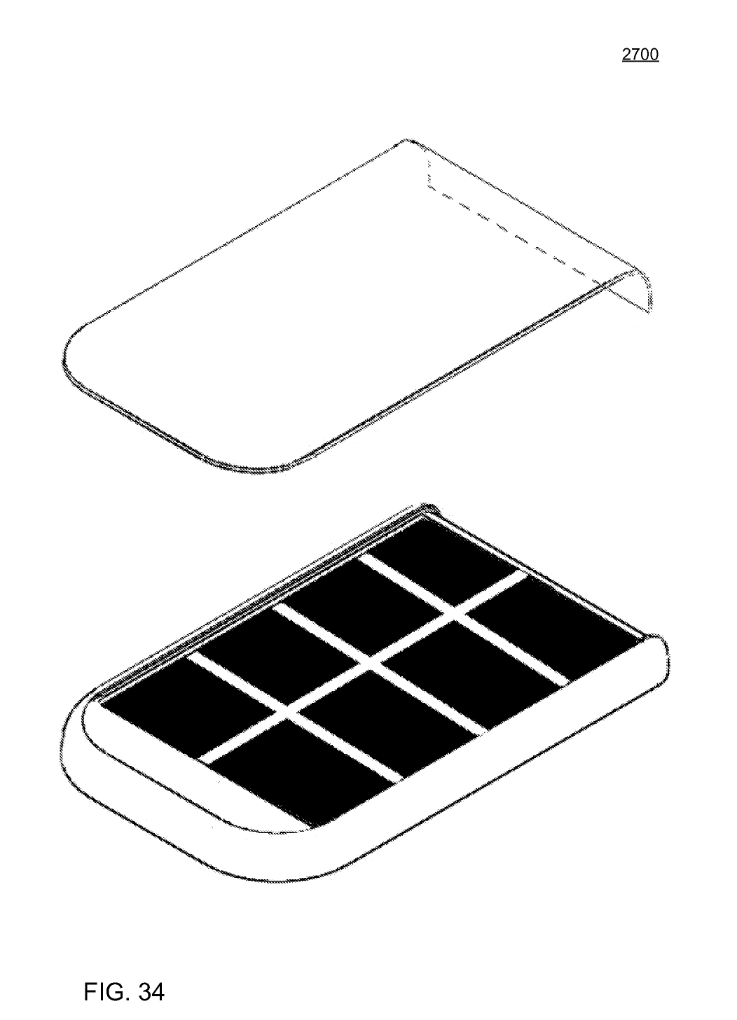

FIG. 22 is an isometric diagram of a bottom/side view of a solar canopy system 1300 without a bottom cover, and having a folding frame in completely folded position, according to an implementation.

### CONCLUSION

A solar canopy is described. A technical effect of the solar canopy is a lightweight solar collector. Although specific implementations are illustrated and described herein, it will be appreciated by those of ordinary skill in the art that any arrangement which is calculated to achieve the same purpose may be substituted for the specific implementations shown. This application is intended to cover any adaptations or variations. For example, although described in the context of wheelchairs, one of ordinary skill in the art will appreciate that implementations can be made for any transportation device.

In particular, one of skill in the art will readily appreciate that the names of the methods and apparatus are not intended to limit implementations. Furthermore, additional methods and apparatus can be added to the components, functions can be rearranged among the components, and new components to correspond to future enhancements and physical devices used in implementations can be introduced without departing from the scope of implementations. One of skill in the art will readily recognize that implementations are applicable to future solar panels, different motorized wheelchairs, and new covers.

The terminology used in this application meant to include solar panel and alternate technologies which provide the same functionality as described herein

1. An apparatus comprising:
a main body having a first recess, the first recess of the main body having an interior length, an interior width and an interior depth, the interior length being at least 20 times the interior depth;
an electrical source in the first recess of the main body, the electrical source having an exterior length, an exterior width and an exterior depth, the exterior length is at least 20 times the exterior depth; the exterior depth of the electrical source being about the same as the interior depth of the first recess of the main body;
the main body further comprising a second recess that is concentric to the first recess, the second recess located on the exterior of the main body, the first recess located inward from the second recess and the exterior of the main body, the second recess having an interior length, an interior width and an interior depth;
a top cover in the second recess, the top cover having an exterior length, an exterior width and an exterior depth, the exterior length of the top cover being about the same as the interior depth of the second recess and the exterior width of the top cover being about the same as the interior width of the second recess;
a frame rotably attached to the main body, the frame having a U geometry;
a battery electrically coupled to the electrical source; and
a drive motor electrically coupled to the battery.

2. The apparatus of claim 1, wherein the electrical source further comprises:
a solar panel.

3. The apparatus of claim 1, wherein the top cover further comprises:
a translucent sheet.

4. The apparatus of claim 3, wherein the translucent sheet further comprises:
a clear sheet.

5. An apparatus comprising:
a main body having a first recess;
an solar panel fitted into the first recess of the main body;
the main body further comprising a second recess;
a top cover fitted into the second recess; and.
a frame rotably attached to the main body, the frame having a U geometry;

6. The apparatus of claim 5, wherein the top cover further comprises:
a clear sheet.

7. The apparatus of claim 5, wherein the apparatus further comprises:
a drive motor electrically coupled to a battery.

8. The apparatus of claim 5, wherein the apparatus further comprises:
the first recess of the main body having an interior length, an interior width and an interior depth, the interior length being at least 20 times the interior depth.

9. The apparatus of claim 8, wherein the apparatus further comprises:
the solar panel having an exterior length, an exterior width and an exterior depth, the exterior length is at least 20 times the exterior depth; the exterior depth of the solar panel being about the same as the interior depth of the first recess of the main body.

10. The apparatus of claim 9, wherein the apparatus further comprises:
the second recess that is concentric to the first recess, the second recess located on the exterior of the main body, the first recess located inward from the second recess and the exterior of the main body, the second recess having an interior length, an interior width and an interior depth.

11. The apparatus of claim 10, wherein the apparatus further comprises:
the top cover having an exterior length, an exterior width and an exterior depth, the exterior length of the top cover being about the same as the interior depth of the second recess and the exterior width of the top cover being about the same as the interior width of the second recess.

12. The apparatus of claim 5, wherein the apparatus further comprises:
a frame rotably attached to the main body, the frame having a U geometry.

13. The apparatus of claim 5, wherein the apparatus further comprises:
a battery electrically coupled to the solar panel.

14. An apparatus comprising:
a main body having a first recess;
an electrical source in the first recess of the main body;
the main body further comprising a second recess; and
a top cover in the second recess.

15. The apparatus of claim 14, wherein the electrical source further comprises:
a solar panel.

16. The apparatus of claim 14, wherein the apparatus further comprises:
a battery electrically coupled to the electrical source; and
a drive motor electrically coupled to the battery.

17. The apparatus of claim 14, wherein the apparatus further comprises:
the first recess of the main body having an interior length, an interior width and an interior depth, the interior length being at least 20 times the interior depth.

18. The apparatus of claim 17, wherein the apparatus further comprises:
the electrical source having an exterior length, an exterior width and an exterior depth, the exterior length is at least 20 times the exterior depth; the exterior depth of the electrical source being about the same as the interior depth of the first recess of the main body.

19. The apparatus of claim 18, wherein the apparatus further comprises:
the second recess that is concentric to the first recess, the second recess located on the exterior of the main body, the first recess located inward from the second recess and the exterior of the main body, the second recess having an interior length, an interior width and an interior depth.

20. The apparatus of claim 14, wherein the apparatus further comprises:
a frame rotably attached to the main body, the frame having a U geometry.
